(19) United States
(12) Patent Application Publication
(10) Pub. No.: US 2023/0335689 A1
(43) Pub. Date: Oct. 19, 2023

(54) DISPLAY DEVICE AND MANUFACTURING METHOD THEREFOR

(71) Applicant: Samsung Display Co., LTD., Yongin-si, Gyeonggi-do (KR)

(72) Inventors: Kyung Bae KIM, Seongnam-Si, Gyeonggi-do (KR); Mee Hye JUNG, Suwon-si, Gyeonggi-do (KR)

(73) Assignee: Samsung Display Co., LTD., Yongin-si, Gyeonggi-do (KR)

(21) Appl. No.: 18/024,875

(22) PCT Filed: Sep. 6, 2021
(86) PCT No.: PCT/KR2021/011999

§ 371 Date: Mar. 6, 2023

(30) Foreign Application Priority Data
Sep. 7, 2020 (KR) 10-2020-0113717

(51) Int. Cl. H01L 33/50; H01L 25/16; H01L 33/62

(52) U.S. Cl. CPC H01L 33/507; H01L 25/167; H01L 33/62; H01L 2933/0041; H01L 2933/0066

(57) ABSTRACT

A display device includes a first base substrate on which a plurality of sub-pixels are defined, a first insulating layer disposed on the first base substrate and including a first and second surfaces, the first surface facing the first base substrate, a plurality of light-emitting elements arranged in each of the plurality of sub-pixels on the first surface of the first insulating layer, a first and second electrodes directly arranged on the first surface of the first insulating layer and electrically contacting each end of each of the light-emitting elements, a circuit layer disposed between the first and second electrodes and the first base substrate and including first transistors electrically connected to the light-emitting elements, a color control structure arranged on the second surface of the first insulating layer and including a light-transmitting layer and wavelength conversion layers, and a color filter layer disposed on the color control structure.

### CROSS REFERENCE TO RELATED APPLICATION(S)

This application is a national entry of International Application No. PCT/KR2021/011999, filed on Sep. 6, 2021, which claims under 35 U.S.C. §§ 119(a) and 365(b) priority to and benefits of Korean Patent Application No. 10-2020-0113717, filed on Sep. 7, 2020, in the Korean Intellectual Property Office (KIPO), the entire content of which are incorporated herein by reference.

### 1. TECHNICAL FIELD

The disclosure relates to a display device including an inorganic light emitting element and a manufacturing method therefor.

### 2. DESCRIPTION OF THE RELATED ART

The importance of a display device is increasing with the development of multimedia. Accordingly, various types of display devices such as an organic light emitting display (OLED) and a liquid crystal display (LCD) are being used.

The display device includes a display panel such as an organic light emitting display panel or a liquid crystal display panel as a device for displaying an image of the display device. The display device may include a light emitting element as a light emitting display panel among the display panels. For example, a light emitting diode (LED) include an organic light emitting diode that uses an organic material as a light emitting material, an inorganic light emitting diode that uses an inorganic material as a light emitting material, and the like.

Aspects of the disclosure provide a display device having improved light efficiency and color matching rate by including an inorganic light emitting element having a novel structure and a color control layer.

Aspects of the disclosure also provide a manufacturing method for a display device that is less restricted in a process of designing and repairing a structure of a light emitting unit.

It should be noted that aspects of the disclosure are not limited thereto and other aspects, which are not mentioned herein, will be apparent to those of ordinary skill in the art from the following description.

### SUMMARY

According to an embodiment of the disclosure, a display device may include a first base substrate on which a plurality of sub-pixels are defined, a first insulating layer disposed on the first base substrate and including a first surface and a second surface, the first surface facing the first base substrate, a plurality of light emitting elements disposed in each of the plurality of sub-pixels on the first surface of the first insulating layer, a first electrode and a second electrode directly disposed on the first surface of the first insulating layer and electrically contacting each end of each of the plurality of light emitting elements, respectively, a circuit layer disposed between the first and second electrodes and the first base substrate and including a first transistor electrically connected to each of the plurality of light emitting elements, a color control structure disposed on the second surface of the first insulating layer and including a light transmission layer and wavelength conversion layers, and a color filter layer disposed on the color control structure.

The display device may further include a first bank disposed on the first surface of the first insulating layer and having a shape protruding toward the first base substrate. The first bank may be disposed at a boundary of the plurality of sub-pixels, and the plurality of light emitting elements, the first electrode, and the second electrode may be disposed in an area surrounded by the first bank.

The circuit layer may further include a lower metal layer disposed between the first transistor and the plurality of light emitting elements, and the lower metal layer may be disposed to overlap the plurality of light emitting elements in a thickness direction of the first base substrate.

The first insulating layer may include a plurality of openings penetrating from the first surface to the second surface, and each of the first electrode and the second electrode may have a portion disposed in one of the plurality of openings.

The first electrode and the second electrode may extend in a direction and be disposed to be spaced apart from each other, and the plurality of light emitting elements may be arranged to be spaced apart in the direction in which the first electrode and the second electrode extend.

The plurality of light emitting elements may include a first light emitting element and a second light emitting element spaced apart from the first light emitting element, the first electrode may electrically contact an end of the first light emitting element, the second electrode may electrically contact an end of the second light emitting element, and the display device may further include a third electrode electrically contacting another end of the first light emitting element and another end of the second light emitting element.

The display device may further include a first pattern having a curved shape in which a portion of sides of each of the first electrode and the second electrode facing each other are depressed.

The display device may further include a bonding agent disposed between the circuit layer and the first base substrate.

The plurality of sub-pixels may include a first sub-pixel and a second sub-pixel, the color control structure may include the light transmission layer disposed in the first sub-pixel and a first wavelength conversion layer disposed in the second sub-pixel, and the color filter layer may include a first color filter layer disposed in the first sub-pixel and a second color filter layer disposed in the second sub-pixel.

The display device may further include a first capping layer disposed on the light transmission layer and the first wavelength conversion layer, and a light blocking member disposed on the first capping layer and surrounding the first color filter layer and the second color filter layer.

The first capping layer may be disposed to surround the light transmission layer and the first wavelength conversion layer, and the display device may further include a color mixing preventing member disposed on the first capping layer between the light transmission layer and the first wavelength conversion layer.

The display device may further include a second bank disposed between the light transmission layer and the first wavelength conversion layer. The first capping layer may be disposed on the second bank.

The display device may further include a second base substrate disposed on the color filter layer and the light blocking member and directly contacting the light blocking member, and a filling layer disposed between the first insulating layer and the color control structure.

Light emitted from the plurality of light emitting elements disposed in the first sub-pixel may pass through the light transmission layer and is emitted through the first color filter layer, and light emitted from the plurality of light emitting elements disposed in the second sub-pixel may pass through the first wavelength conversion layer and be emitted through the second color filter layer.

The plurality of light emitting elements disposed in the first sub-pixel and the second sub-pixel may emit light of a first color, the first sub-pixel may emit light of the first color, and the second sub-pixel may emit light of a second color different from the first color.

The plurality of sub-pixels may further include a third sub-pixel, the color control structure may further include a second wavelength conversion layer disposed in the third sub-pixel, the color filter layer may further include a third color filter layer disposed in the third sub-pixel, and light emitted from the plurality of light emitting elements disposed in the third sub-pixel may pass through the second wavelength conversion layer and emitted as light of a third color different from the first color and the second color through the third color filter layer.

According to an embodiment of the disclosure, a manufacturing method for a display device may include preparing an alignment substrate including a target substrate and alignment electrodes disposed to be spaced apart from each other on the target substrate, forming a display element substrate by disposing light emitting elements on a first surface of a first insulating layer disposed on the alignment substrate, forming a plurality of electrodes and a circuit layer on the light emitting elements, and bonding the display element substrate on which the circuit layer is formed to a first base substrate, removing the alignment substrate from the display element substrate to expose a second surface of the first insulating layer, and disposing a color control structure and a color filter layer on the second surface of the first insulating layer.

The alignment substrate may further include an auxiliary layer disposed on the target substrate, and the alignment electrodes may include a first alignment electrode and a second alignment electrode extending in a direction and disposed to be spaced apart from each other.

The plurality of electrodes may include a first electrode and a second electrode disposed directly on the first surface of the first insulating layer and electrically contacting each end of each of the light emitting elements, respectively, and the forming of the display element substrate may include forming the first electrode and the second electrode after the disposing of the light emitting elements on the first surface of the first insulating layer by generating an electric field on the alignment electrodes.

The circuit layer may be disposed on the light emitting elements and the plurality of electrodes.

The forming of the display element substrate may further include forming a first pattern by removing a portion where the first electrode and the second electrode are connected to each other.

The removing of the alignment substrate from the display element substrate may include separating the target substrate from the auxiliary layer, and etching and removing the auxiliary layer and the alignment electrodes.

The disposing of the color control structure and the color filter layer may include directly disposing the color control structure on the second surface of the first insulating layer.

The disposing of the color control structure and the color filter layer may include preparing a second base substrate, forming the color filter layer and the color control structure on the second base substrate, and bonding the color control structure and the second surface of the first insulating layer to each other using a filler.

The details of other embodiments are included in the detailed description and the accompanying drawings.

The display device according to an embodiment may include a display layer and a color control layer disposed on a substrate, and the color control layer and light emitting elements may be disposed adjacent to each other with an insulating layer interposed therebetween. Since a distance between the light emitting elements and the color control layer is narrow, most of the light emitted from the light emitting elements may be incident on the color control layer, and light efficiency and color matching rate of the display device may be improved.

Further, the manufacturing method for the display device according to an embodiment may have an advantage in that since the process of disposing the light emitting elements is performed using a separate substrate not included in the display device, a structure of the light emitting unit including the light emitting element may be designed within a limited space, and there are less restrictions on a process of repairing the light emitting unit.

The effects according to the embodiments are not limited by the contents above, and more various effects are included in this disclosure.

### BRIEF DESCRIPTION OF THE DRAWINGS

FIG. 1 is a schematic plan view of a display device according to an embodiment;

FIG. 2 is a schematic plan view illustrating one pixel of the display device according to an embodiment;

FIG. 3 is a schematic plan view illustrating a light emitting element and electrodes disposed in one pixel of FIG. 2;

FIG. 4 is a schematic cross-sectional view illustrating one pixel of the display device according to an embodiment;

FIG. 5 is a schematic cross-sectional view taken along line Q1-Q1′ of FIGS. 2 and 3;

FIG. 6 is schematic diagram of an equivalent circuit of one sub-pixel according to an embodiment;

FIG. 7 is a schematic view of a light emitting element according to an embodiment;

FIGS. 8 to 20 are views sequentially illustrating steps in a manufacturing process of a display element layer of a display device according to an embodiment;

FIGS. 21 to 25 are views sequentially illustrating steps in a manufacturing process of a color control layer of a display device according to an embodiment;

FIG. 26 is a schematic plan view illustrating an arrangement of light emitting elements and electrodes of one sub-pixel according to another embodiment;

FIG. 27 is a schematic plan view illustrating an arrangement of light emitting elements and electrodes of one sub-pixel according to still another embodiment;

FIG. 28 is a schematic cross-sectional view illustrating one pixel of a display device according to another embodiment;

FIGS. 29 to 31 are schematic cross-sectional views illustrating steps in a manufacturing process of a color control layer of the display device of FIG. 28;

FIG. 32 is a schematic cross-sectional view illustrating one pixel of a display device according to still another embodiment;

FIGS. 33 to 35 are schematic cross-sectional views illustrating steps in a manufacturing process of a color control layer of the display device of FIG. 32;

FIG. 36 is a schematic cross-sectional view illustrating one pixel of a display device according to another embodiment;

FIG. 37 is a schematic cross-sectional view illustrating one pixel of a display device according to still another embodiment;

FIGS. 38 and 39 are schematic cross-sectional views illustrating one pixel of a display device according to still another embodiment; and

FIG. 40 is a schematic plan view illustrating an arrangement of light emitting elements and electrodes of one sub-pixel of a display device according to another embodiment.

### DETAILED DESCRIPTION OF EMBODIMENTS

The embodiment will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element. Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

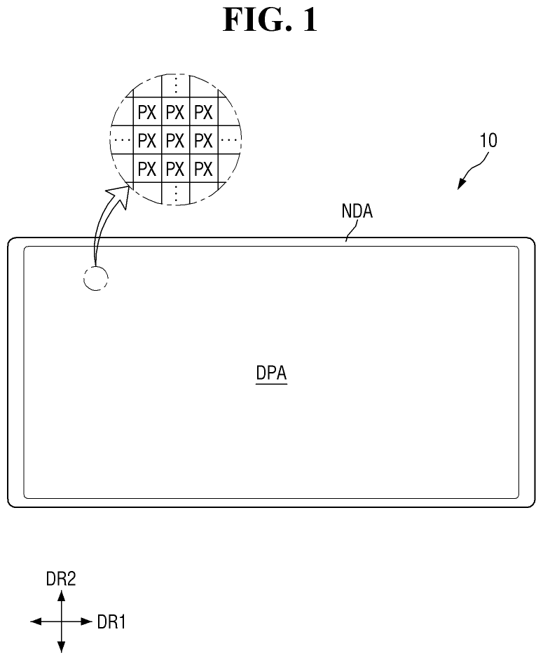

FIG. 1 is a schematic plan view of a display device according to an embodiment.

Referring to FIG. 1, a display device 10 may display a moving image or a still image. The display device 10 may be any electronic device that provides a display screen. For example, the display device 10 may be televisions, laptop computers, monitors, billboards, Internet of things, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, and the like that includes a display screen.

The display device 10 may include a display panel for providing a display screen. Examples of the display panel may include an inorganic light emitting diode display panel, an organic light emitting display panel, a quantum dot light emitting display panel, a plasma display panel, and a field emission display panel. Hereinafter, it is illustrated that an inorganic light emitting diode display panel is used as an embodiment of the display panel, but the disclosure is not limited thereto and may be applied to other display panels as long as the same technical concept is applicable.

A shape of the display device 10 may be variously changed. For example, the display device 10 may have a shape such as a rectangle with a long width, a rectangle with a long length, a square, a quadrangle with rounded corners (vertices), other polygons, or a circle. A shape of a display area DPA of the display device 10 may be similar to an overall shape of the display device 10. In FIG. 1, the display device 10 and the display area DPA that have a rectangular shape with a long width are illustrated.

The display device 10 may include a display area DPA and a non-display area NDA. The display area DPA may be an area in which an image may be displayed, and the non-display area NDA may be an area in which an image is not displayed. The display area DPA may be referred to as an active area, and the non-display area NDA may be referred to as a non-active area. The display area DPA may generally occupy the center of the display device 10.

The display area DPA may include multiple pixels PX. The pixels PX may be arranged in matrix. Each pixel PX may have a rectangular shape or a square shape in plan view, but the disclosure is not limited thereto, and may also have a rhombic shape of which each side is inclined with respect to a direction. Each pixel PX may be alternately arranged in a stripe pattern or a PenTile™ pattern. Each of the pixels PX may include one or more light emitting elements ED emitting light in a specific wavelength band to display a specific color.

The non-display area NDA may be disposed adjacent to the display area DPA. The non-display area NDA may entirely or partially surround the display area DPA. The display area DPA may have a rectangular shape, and the non-display area NDA may be disposed adjacent to four sides of the display area DPA. The non-display area NDA may constitute a bezel of the display device 10. Lines or circuit driving units included in the display device 10 may be disposed in the non-display areas NDA, or external devices may be mounted thereon.

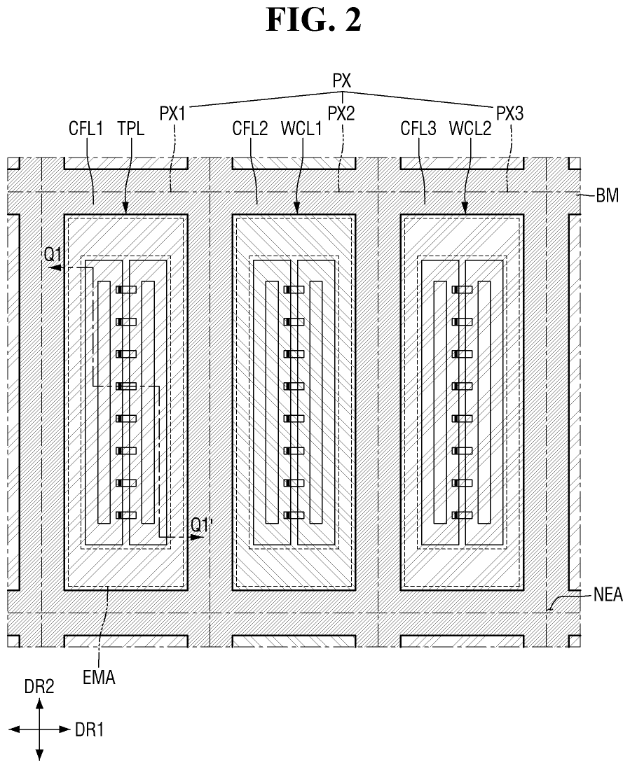

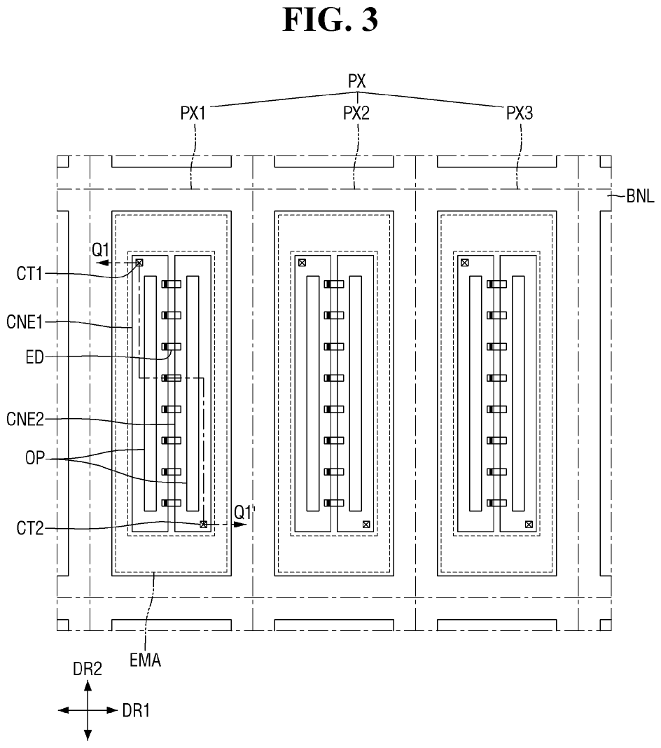

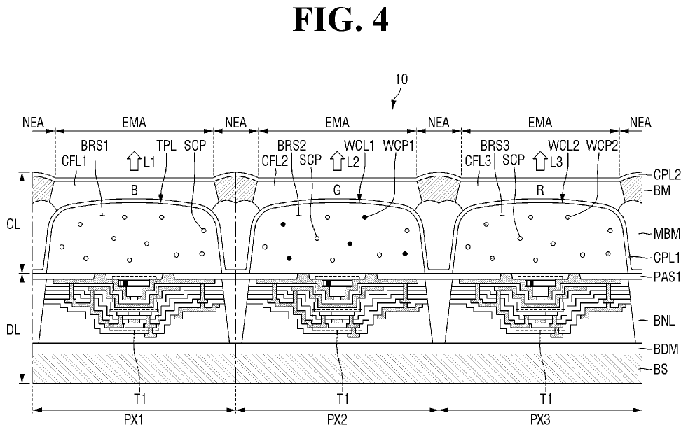

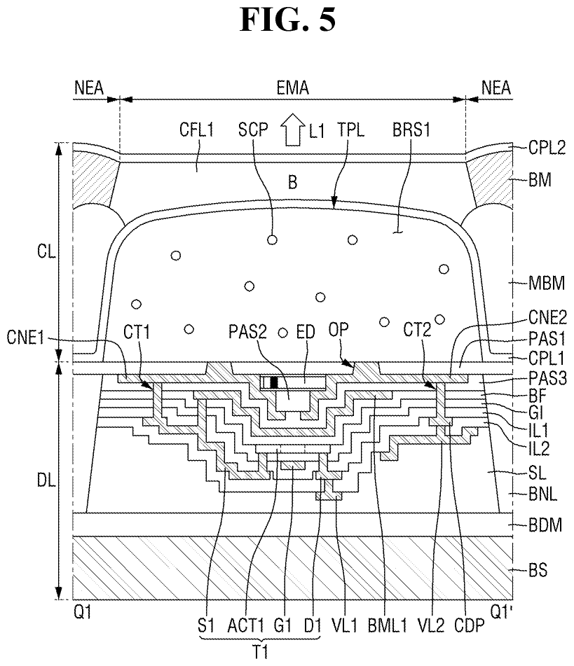

FIG. 2 is a schematic plan view illustrating one pixel of the display device according to an embodiment. FIG. 3 is a schematic plan view illustrating a light emitting element and electrodes disposed in one pixel of FIG. 2. FIG. 4 is a schematic cross-sectional view illustrating one pixel of the display device according to an embodiment. FIG. 5 is a schematic cross-sectional view taken along line Q1-Q1′ of FIGS. 2 and 3.

FIG. 2 schematically illustrates a planar arrangement of a display layer DL and a color control layer CL in one pixel PX of the display device 10, and FIG. 3 illustrates a planar arrangement of a light emitting element ED and electrodes CNE1 and CNE2 of the display layer DL. FIG. 4 schematically illustrates an arrangement of the display layer DL and the color control layer CL in cross-sectional view based on a first bank BNL disposed across a boundary of multiple sub-pixels PXn in one pixel PX of the display device 10, and FIG. 5 illustrates a cross section of the light emitting element ED and a cross section of the color control layer CL in one sub-pixel PX.

Referring to FIGS. 2 to 5, each of the of pixels PX may include multiple sub-pixels PXn (n may be an integer of 1 to 3). For example, one pixel PX may include a first sub-pixel PX1, a second sub-pixel PX2, and a third sub-pixel PX3. The first sub-pixel PX1 may emit light L1 of a first color, the second sub-pixel PX2 may emit light L2 of a second color, and the third sub-pixel PX3 may emit light L3 of a third color. The first color may be blue, the second color may be green, and the third color may be red. It is illustrated in the drawings that one pixel PX includes three sub-pixels PXn, but the disclosure is not limited thereto, and the pixel PX may include a larger number of sub-pixels PXn.

Each of the sub-pixels PXn of the display device 10 may include an emitting material area EMA and a non-emitting material area NEA. The emitting material area EMA may be an area in which the light emitting element ED is disposed to emit light in a specific wavelength band, and the non-emitting material area NEA may be an area in which the light emitting element ED is not disposed and the light is not emitted because the light does not reach the area.

The display device 1 according to an embodiment may include a first base substrate BS, and a light emitting element ED, electrodes CNE1 and CNE2, color control structures TPL, WCL1, and WLC2, and color filter layers CFL1, CFL2 and CFL3 disposed on the first base substrate BS. The display device 10 may also include a circuit layer disposed between the light emitting element ED and the first base substrate BS. The circuit layer, the light emitting element ED, the electrodes CNE1 and CNE2, the color control structures TPL, WCL1, and WCL2, and the color filter layers CFL1, CFL2, and CFL3 may be sequentially disposed on the first base substrate BS. The display layer DL of the display device 10 may include the first base substrate BS, the circuit layer, and the light emitting elements ED, and the color control layer CL may include the color control structures TPL, WCL1, and WCL2 and the color filter layers CFL1, CFL2, and CFL3.

In the display device 10, the light emitting element ED that emits light in a specific wavelength band and the color control structures TPL, WCL1, and WLC2 that convert the light into light of different colors may be directly disposed on a surface (or a first surface) and another surface (or a second surface) of a first insulating layer PAS1, respectively. As a distance between the light emitting elements ED and the color control structures TPL, WCL1, and WLC2 is minimized, most of the light emitted from the light emitting elements ED may be incident on the color control structures TPL, WCL1, and WCL2. Since the light may be directly incident on the color control structures TPL, WCL1, and WCL2 without being reflected by other members, light emitting efficiency and color matching rate of the display device 10 may be improved. Hereinafter, each of the components of the display device 10 will be described in detail.

The first base substrate BS may be an insulating substrate. The first base substrate BS may be made of an insulating material such as glass, quartz, or a polymer resin. The first base substrate BS may be a rigid substrate, or may be a flexible substrate capable of being bent, folded, or rolled. The sub-pixels PXn may be defined on the first base substrate BS, and may include multiple emitting material areas EMA and non-emitting material areas NEA.

The display layer DL may include the first base substrate BS and the first insulating layer PAS1 facing the first base substrate BS, and the light emitting element ED and the circuit layer of the display layer DL may be disposed between the first insulating layer PAS1 and the first base substrate BS. In an embodiment, the light emitting element ED may be directly disposed on the first surface of the first insulating layer PAS1 facing the first base substrate BS, and the circuit layer may be disposed between the light emitting element ED and the first base substrate BS. Hereinafter, with respect to the description of the display layer DL, the light emitting element ED, the electrodes CNE1 and CNE2, and the circuit layer disposed on the first surface of the first insulating layer PAS1 will be described based on the first insulating layer PAS1. For example, layers stacked from the first surface of the first insulating layer PAS1 in a downward direction based on FIG. 5 will be sequentially described.

The first insulating layer PAS1 may be disposed on the first base substrate BS to face the first base substrate BS. The first insulating layer PAS1 may include a first surface on which the light emitting element ED is disposed and a second surface on which the color control structures TPL, WCL1, and WCL2, which will be described later, are disposed. The first insulating layer PAS1 may include an insulating material and the first surface and the second surface of the first insulating layer PAS1 may be formed to be flat. The first insulating layer PAS1 may have a thickness less than a thickness of the first base substrate BS. Since the light emitting element ED and the color control structures TPL, WCL1, and WCL2 disposed on the first surface and the second surface of the first insulating layer PAS1, respectively, may be disposed adjacent to each other with only the first insulating layer PAS1 interposed therebetween, most of the light emitted from the light emitting elements ED may be incident on the color control structures TPL, WCL1, and WCL2.

A first bank BNL may be disposed on the first surface of the first insulating layer PAS1, for example, on a lower surface of the first insulating layer PAS1 in the drawing. The first bank BNL may be disposed in a grid pattern on an entire surface of the display area DPA by including portions extending in the first direction DR1 and the second direction DR2 in plan view. The first bank BNL may be disposed across a boundary between the respective sub-pixels PXn to distinguish adjacent sub-pixels PXn of the display layer DL from each other.

The first bank BNL may have a shape protruding toward the first base substrate BS from the first surface of the first insulating layer PAS1. The first bank BNL may be formed to have a height of a certain level or more, and may prevent ink from overflowing to the adjacent sub-pixels PXn in an inkjet printing process during the manufacturing process of the display device 10. The first bank BNL may include polyimide PI, but the disclosure is not limited thereto.

The light emitting element ED may be directly disposed on the first surface of the first insulating layer PAS1. The light emitting elements ED may be disposed to be spaced apart from each other in the second direction DR2 in plan view and may be aligned to be substantially parallel to each other. The light emitting element ED may have a shape extending in a direction, and a direction in which each of the electrodes CNE1 and CNE2 extends and a direction in which the light emitting element ED extends may be substantially perpendicular to each other. However, the light emitting element ED is not limited thereto, and may also be disposed to be oblique to the direction in which each of the electrodes CNE1 and CNE2 extends.

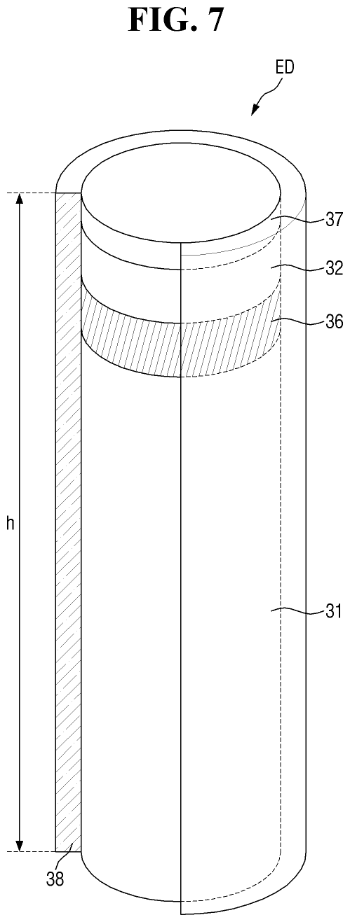

The light emitting elements ED disposed in each sub-pixel PXn may include a light emitting layer (‘36’ in FIG. 7) and may emit light in a specific wavelength band. The light emitting element ED may emit light in different wavelength bands depending on a material constituting the light emitting layer 36. However, since the display device 10 includes the color control structures TPL, WCL1, and WCL2 and the color filter layers CFL1, CFL2, and CFL3, the display device 10 may display a different color for each of the sub-pixels PXn even in case that the light emitting elements ED disposed in each of the sub-pixels PXn emit light of a same color. In an embodiment, each of the sub-pixels PXn of the display device 10 may include the light emitting elements ED emitting the light L1 of the first color, and may display lights of different colors. For example, the first sub-pixel PX1, the second sub-pixel PX2, and the third sub-pixel PX3 may emit the light L1 of the first color, the light L2 of the second color, and the light L3 of the third color, respectively. However, each of the sub-pixels PXn is not limited thereto, and may include different types of light emitting elements ED in some embodiments.

The light emitting element ED may have multiple layers disposed in a direction perpendicular to the first surface of the first insulating layer PAS1. The light emitting element ED may be disposed so that an extended direction thereof is parallel to the first surface of the first insulating layer PAS1, and multiple semiconductor layers included in the light emitting element ED may be sequentially disposed in a direction parallel to the first surface of the first insulating layer PAS1. However, the disclosure is not limited thereto, and in case that the light emitting element ED has another structure, the semiconductor layers may be disposed in the direction perpendicular to the first surface of the first insulating layer PAS1.

Each end of the light emitting element ED may be in contact with the electrodes CNE1 and CNE2, respectively. For example, an insulating film (‘38’ in FIG. 7) may not be formed on an end surface of the light emitting element ED in the extended direction and a portion of the semiconductor layer may be exposed therefrom, and the exposed semiconductor layer may be in contact with the electrodes CNE1 and CNE2. However, the disclosure is not limited thereto, and in the light emitting element ED, at least a partial area of the insulating film 38 may be removed, such that side surfaces of both ends of the semiconductor layers may be partially exposed. The exposed side surfaces of the semiconductor layers may be in direct contact with the electrodes CNE1 and CNE2.

The second insulating layer PAS2 may be disposed on a partial area of the light emitting element ED. For example, the second insulating layer PAS2 may be disposed on the light emitting element ED and may have a width less than a length of the light emitting element ED to expose both ends of the light emitting element ED while covering the light emitting element ED. The second insulating layer PAS2 may be formed by forming to cover the light emitting elements ED and the first insulating layer PAS1 and a portion removed to expose both ends of the light emitting element ED during the manufacturing process of the display device 10. The second insulating layer PAS2 may protect the light emitting element ED and fix the light emitting element ED in the manufacturing process of the display device 10.

The electrodes CNE1 and CNE2 may be disposed on the first surface of the first insulating layer PAS1. The electrodes CNE1 and CNE2 may include a first electrode CNE1 and a second electrode CNE2, and the first electrode CNE1 and the second electrode CNE2 may be disposed to be spaced apart from each other in the first direction DR1. A gap between the first electrode CNE1 and the second electrode CNE2 may be shorter than the extended length of the light emitting element ED. The first electrode CNE1 and the second electrode CNE2 may be formed in a process after disposing the light emitting elements ED on the first surface of the first insulating layer PAS1. The first electrode CNE1 may be disposed to cover a first end of the light emitting element ED, and the second electrode CNE2 may be disposed to cover a second end of the light emitting element ED. Each of the electrodes CNE1 and CNE2 may be disposed such that a portion thereof is placed on a surface of the second insulating layer PAS2, for example, a lower surface of the second insulating layer PAS2 in the drawing. The semiconductor layer may be exposed from both end surfaces of the light emitting element ED in the direction in which the light emitting element ED extends, and each of the electrodes CNE1 and CNE2 may be in electrically contact with and electrically connected to the semiconductor layer of the light emitting element ED.

Each of the first electrode CNE1 and the second electrode CNE2 may be disposed in a shape extending in the second direction DR2 within the emitting material area EMA of the sub-pixel PXn. The first electrode CNE1 and the second electrode CNE2 may be disposed in the emitting material area EMA so as not to cross over to the sub-pixels PXn adjacent to each other in the second direction DR2. The first electrode CNE1 and the second electrode CNE2 may be disposed in a stripe pattern within the emitting material area EMA of each of the sub-pixels PXn.

The electrodes CNE1 and CNE2 may include a transparent conductive material. For example, the electrodes CNE1 and CNE2 may include ITO, IZO, ITZO, aluminum (Al), or the like. The light emitted from the light emitting element ED may be transmitted through the electrodes CNE1 and CNE2. However, the disclosure is not limited thereto.

Although it is illustrated in the drawings that one first electrode CNE1 and one second electrode CNE2 are disposed in each sub-pixel PXn, the disclosure is not limited thereto, and a larger numbers of first electrodes CNE1 and second electrodes CNE2 may be disposed in each sub-pixel PXn. The first electrode CNE1 and the second electrode CNE2 disposed in each of the sub-pixels PXn may not necessarily have a shape extending in one direction, and the first electrode CNE1 and the second electrode CNE2 may be disposed in various structures. For example, the first electrode CNE1 and the second electrode CNE2 may have a partially curved or bent shape, and one of the first electrode CNE1 and the second electrode CNE2 may be disposed to surround another one of the first electrode CNE1 and the second electrode CNE2.

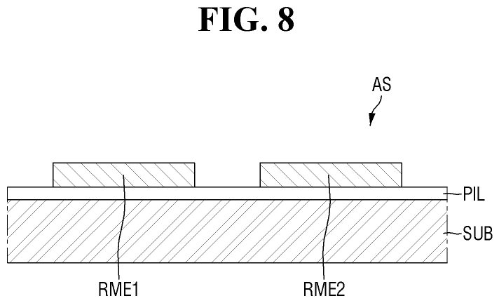

According to an embodiment, the first insulating layer PAS1 may include multiple openings OP penetrating therethrough, and the first electrode CNE1 and the second electrode CNE2 may be disposed in each opening OP. The first electrode CNE1 and the second electrode CNE2 may be disposed on the first surface of the first insulating layer PAS1, and as the first electrode CNE1 and the second electrode CNE2 are disposed in the opening OP penetrating the first insulating layer PAS1, a portion of each of the electrodes CNE1 and CNE2 may be also placed on the second surface of the first insulating layer PAS1. During the manufacturing process of the display device 10, a process of disposing the light emitting elements ED, the electrodes CNE1 and CNE2, and the circuit layer on the first insulating layer PAS1 using an alignment substrate (‘AS’ in FIG. 8) and removing the alignment substrate AS may be performed. The first electrode CNE1 and the second electrode CNE2 may be in contact with alignment electrodes (‘RME1’ and ‘RME2’ in FIG. 8) of the alignment substrate AS through the openings OP penetrating through the first insulating layer PAS1, respectively. Portions of the electrodes CNE1 and CNE2 disposed in the opening OP may be left portions where the electrodes CNE1 and CNE2 are connected to the alignment electrodes RME1 and RME2 during the manufacturing process.

Each of the first electrode CNE1 and the second electrode CNE2 may be electrically connected to the circuit layer. The first electrode CNE1 may be electrically connected to a first voltage line VL1 through a first transistor T1, and the second electrode CNE2 may be electrically connected to a second voltage line VL2 through a first conductive pattern CDP. An electric signal for emitting light of the light emitting element ED may be applied to each of the electrodes CNE1 and CNE2.

A third insulating layer PAS3 may be disposed on the first surface of the first insulating layer PAS1 to cover the light emitting element ED, the second insulating layer PAS2, and the electrodes CNE1 and CNE2. The third insulating layer PAS3 may prevent direct contact between the light emitting elements ED and the circuit layer disposed, and the electrodes CNE1 and CNE2 disposed on the first base substrate BS. However, the third insulating layer PAS3 may be omitted.

Each of the first insulating layer PAS1, the second insulating layer PAS2, and the third insulating layer PAS3 described above may include an inorganic insulating material or an organic insulating material. For example, the first insulating layer PAS1, the second insulating layer PAS2, and the third insulating layer PAS3 may include an inorganic insulating material such as silicon oxide (SiOₓ), silicon nitride (SiNₓ), silicon oxynitride (SiOₓN_{y}), aluminum oxide (AlO_{y}), or aluminum nitride (AlₓN_{y}). In another example, the first insulating layer PAS1, the second insulating layer PAS2, and the third insulating layer PAS3 may include an organic insulating material such as an acrylic resin, an epoxy resin, a phenolic resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, polymethylmethacrylate, polycarbonate, or a polymethylmethacrylate-polycarbonate synthetic resin. However, the disclosure is not limited thereto.

The circuit layer may be disposed on a surface of the third insulating layer PAS3, for example, on a lower surface in the drawing. The circuit layer may include at least one first transistor T1 and may transmit an electrical signal to the light emitting element ED. The circuit layer may include a lower metal layer BML1, a semiconductor layer, a gate conductive layer, and data conductive layers, and multiple insulating layers therebetween. The circuit layer may be disposed in each of the sub-pixels PXn in an area surrounded by the first bank BNL. However, the disclosure is not limited thereto, and some lines of the circuit layer may extend beyond the first bank BNL to other sub-pixels PXn.

For example, the lower metal layer BML1 may be disposed on a surface of the third insulating layer PAS3 facing the first base substrate BS. The lower metal layer BML1 may overlap an active layer ACT1 of the first transistor T1 of the display device 10. The lower metal layer BML1 may include a material blocking light to prevent the light from being incident on the first active layer ACT1 of the first transistor T1. For example, the lower metal layer BML1 may be formed of an opaque metal blocking transmission of light. However, the disclosure is not limited thereto, and in some embodiments, the lower metal layer BML1 may be omitted.

In an embodiment, the lower metal layer BML1 may be disposed to overlap the light emitting elements ED in a thickness direction. For example, a width of the lower metal layer BML1 may be greater than a length of the light emitting element ED, such that the lower metal layer BML1 may be disposed to cover the light emitting elements ED in the thickness direction in a plan view. In case that the lower metal layer BML1 is formed of a metal that blocks transmission of light, the lower metal layer BML1 may reflect light incident on the lower metal layer BML1. In an embodiment, as the lower metal layer BML1 is disposed to cover the light emitting elements ED, the lower metal layer BML1 may reflect light emitted from the light emitting element ED and directed toward the lower metal layer BML1 toward the second surface of the first insulating layer PAS1.

A buffer layer BF may be entirely disposed on a surface of the lower metal layer BML1 and the third insulating layer PAS3. The buffer layer BF may be formed as a single layer or multiple inorganic layers in which multiple layers are alternately stacked each other. For example, the buffer layer BF may be formed as multiple layers in which inorganic layers including at least one of silicon oxide (SiOₓ), silicon nitride (SiNₓ), and silicon oxynitride (SiOₓN_{y}) are alternately stacked each other, or a double layer in which silicon oxide (SiOₓ) and silicon nitride (SiNₓ) are sequentially stacked.

The semiconductor layer may be disposed on a surface of the buffer layer BF, for example, on a lower surface in the drawing. The semiconductor layer may include the active layer ACT1 of the first transistor T1. The active layer ACT1 may be disposed to partially overlap a gate electrode G1 or the like of a first conductive layer to be described later.

The semiconductor layer may include polycrystalline silicon, single crystal silicon, an oxide semiconductor, or the like. In case that the semiconductor layer includes an oxide semiconductor, each active layer ACT1 may include multiple conductive regions and a channel region therebetween. The oxide semiconductor may be an oxide semiconductor containing indium (In). For example, the oxide semiconductor may be indium tin oxide (ITO), indium zinc oxide (IZO), indium gallium oxide (IGO), indium zinc tin Oxide (IZTO), indium gallium tin oxide (IGTO), indium gallium zinc oxide (IGZO), or indium gallium zinc tin oxide (IGZTO).

In another embodiment, the semiconductor layer may include polycrystalline silicon. The polycrystalline silicon may be formed by crystallizing amorphous silicon, and each of the conductive regions of the active layer ACT1 may be doped with impurities.

A first gate insulating layer GI may be disposed on a surface of the semiconductor layer and the buffer layer BF. The first gate insulating layer GI may function as a gate insulating film of each of the transistors. The first gate insulating layer GI may be formed as an inorganic layer including an inorganic material, for example, silicon oxide (SiOₓ), silicon nitride (SiNₓ), or silicon oxynitride (SiOₓN_{y}), or may be formed as a double layer in which the inorganic layer is stacked or multiple layers in which the inorganic layers are alternately stacked each other.

The first gate conductive layer may be disposed on the first gate insulating layer GI. The first gate conductive layer may include a gate electrode G1 of the first transistor T1. The gate electrode G1 may be disposed to overlap the channel region of the active layer ACT1 in the thickness direction. The first gate conductive layer may be formed as a single layer or multiple layers made of at least one of molybdenum (Mo), aluminum (Al), chromium (Cr), gold (Au), titanium (Ti), nickel (Ni), neodymium (Nd), and copper (Cu), or an alloy thereof. However, the disclosure is not limited thereto.

A first interlayer insulating layer IL1 may be disposed to cover the first gate conductive layer. The first interlayer insulating layer IL1 may serve as an insulating film between the first gate conductive layer and other layers disposed on a lower side of the first gate conductive layer. The first interlayer insulating layer IL1 may serve to protect the first gate conductive layer. The first interlayer insulating layer IL1 may be formed as an inorganic layer including an inorganic material, for example, silicon oxide (SiOₓ), silicon nitride (SiNₓ), or silicon oxynitride (SiOₓN_{y}), or may be formed as a double layer in which the inorganic layer is stacked or multiple layers in which the inorganic layers are alternately stacked each other.

A first data conductive layer may be disposed on a surface of the first interlayer insulating layer ILL The first data conductive layer may include a first source electrode Si and a first drain electrode D1 of the first transistor T1 and a first conductive pattern CDP.

The first source electrode Si and the first drain electrode D1 of the first transistor T1 may be in contact with the doped region of the active layer ACT1 through a contact hole penetrating through the first interlayer insulating layer IL1 and the first gate insulating layer GI, respectively. The source electrode S1 of the first transistor T1 may be in contact with the first electrode CNE1 through another contact hole. The lower metal layer, for example, the first source electrode S1 of the first transistor T1 may be in contact with the first electrode CNE1 through a first contact hole CT1 penetrating through the first interlayer insulating layer ILL the first gate insulating layer GI, the buffer layer BF, and the third insulating layer PAS3. The first source electrode Si is not limited thereto and may be in contact with the lower metal layer BML1 through another contact hole. Similarly, the first conductive pattern CDP may be in contact with the second electrode CNE2 through a second contact hole CT2 penetrating through the first interlayer insulating layer ILL the first gate insulating layer GI, the buffer layer BF, and the third insulating layer PAS3.

The first data conductive layer may be formed as a single layer or multiple layers made of at least one of molybdenum (Mo), aluminum (Al), chromium (Cr), gold (Au), titanium (Ti), nickel (Ni), neodymium (Nd), and copper (Cu), or an alloy thereof. However, the disclosure is not limited thereto.

A second interlayer insulating layer IL2 may be disposed to cover the first data conductive layer. The second interlayer insulating layer IL2 may serve as an insulating film between the first data conductive layer and other layers disposed on a lower side of the first data conductive layer. The second interlayer insulating layer IL2 may serve to protect the first data conductive layer. The second interlayer insulating layer IL2 may be formed as an inorganic layer including an inorganic material, for example, silicon oxide (SiOₓ), silicon nitride (SiNₓ), or silicon oxynitride (SiOₓN_{y}), or may be formed as a double layer in which the inorganic layer is stacked or multiple layers in which the inorganic layers are alternately stacked each other.

The second data conductive layer may be disposed on a surface of the second interlayer insulating layer IL2 or on a lower side of the second interlayer insulating layer IL2 in the drawing. The second data conductive layer may include a first voltage line VL1 and a second voltage line VL2. The first voltage line VL1 may be applied with a high potential voltage (or first power supply voltage) supplied to the first transistor T1, and the second voltage line VL2 may be applied with a low potential voltage (or second power supply voltage) supplied to the second electrode CNE2. The first voltage line VL1 may be in contact with the first drain electrode D1 through a contact hole penetrating through the second interlayer insulating layer IL2. The first voltage line VL1 may be electrically connected to the first electrode CNE1 through the first transistor T1, and the first power supply voltage may be transferred to the first electrode CNE1. The second voltage line VL2 may be in contact with the first conductive pattern CDP through a contact hole penetrating through the second interlayer insulating layer IL2. The second voltage line VL2 may be electrically connected to the second electrode CNE2 through the first conductive pattern CDP, and the second power supply voltage may be transferred to the second electrode CNE2.

The second data conductive layer may be formed as a single layer or multiple layers made of at least one of molybdenum (Mo), aluminum (Al), chromium (Cr), gold (Au), titanium (Ti), nickel (Ni), neodymium (Nd), and copper (Cu), or an alloy thereof. However, the disclosure is not limited thereto.

It is illustrated in the drawing that only one first transistor T1 is disposed in the circuit layer, but the disclosure is not limited thereto. The circuit layer of the display device 10 may include a larger number of transistors, storage capacitors, and lines in addition to the first transistor T1 by including more lines, electrodes, and semiconductor layers. For example, the display device 10 may include two or three transistors and one storage capacitor by further including one or more transistors in addition to the first transistor T1 for each of the sub-pixels PXn.

A first planarization layer SL may be disposed to cover the second data conductive layer. The first planarization layer SL may include an organic insulating material, for example, an organic material such as polyimide (PI), and serve to planarize a step formed by the first bank BNL and the circuit layers. However, the first planarization layer SL may also be omitted.

A bonding agent BDM may be disposed between the first planarization layer SL and the first base substrate BS. The bonding agent BDM may mutually bond the circuit layer disposed on the first surface of the first insulating layer PAS1 to the first base substrate BS. During the manufacturing process of the display device 10, the light emitting element ED, the electrodes CNE1 and CNE2, and the circuit layer may be sequentially formed on the first insulating layer PAS1, and the light emitting element ED, the electrodes CNE1 and CNE2, and the circuit layer may be bonded to the first base substrate BS through the bonding agent BDM.

A color control layer CL may be disposed on the second surface of the first insulating layer PAS1 or on the display layer DL. In the color control layer CL, the color control structures TPL, WCL1, and WCL2 and the color filter layers CFL1, CFL2, and CFL3 may be sequentially disposed on the second surface of the first insulating layer PAS1.

In an embodiment, the color control structures TPL, WCL1, and WCL2 may be directly disposed on the second surface of the first insulating layer PAS1. The color control structures TPL, WCL1, and WCL2 may be disposed in each of the sub-pixels PXn in the emitting material area EMA surrounded by the first bank BNL. According to an embodiment, the color control structures TPL, WCL1, and WCL2 may be disposed to correspond to the emitting material area EMA of the display layer DL, and a width of each of the color control structures TPL, WCL1, and WCL2 measured in the first direction DR1 may be less than a width of each of the color filter layers CFL1, CFL2, and CFL3 to be described later in the first direction DR1. The color filter layers CFL1, CFL2, and CFL3 may be disposed in an area surrounded by a light blocking member BM, but the disclosure is not limited thereto. In some embodiments, a width of the light blocking member BM may be less than that of the first bank BNL, and the color filter layers CFL1, CFL2, and CFL3 may partially overlap the first bank BNL in the thickness direction. In another embodiment, the width of the light blocking member BM may be greater than that of the first bank BNL. Since each of the color control structures TPL, WCL1, and WCL2 have substantially the same width as the width of the light emitting area EMA surrounded by the first bank BNL, the widths of the color control structures TPL, WCL1, and WCL2 may be greater or less than those of the color filter layers CFL1, CFL2, and CFL3 according to the width of the light blocking member BM. The color control structures TPL, WCL1, and WCL2 may be disposed in an island-shaped pattern on an entire area of the display area DPA.

In an embodiment in which the light emitting elements ED of each of the sub-pixels PXn emits the light L1 of the first color, the color control structures TPL, WCL1, and WCL2 may include a light transmission layer TPL disposed in the first sub-pixel PX1, a first wavelength conversion layer WCL1 disposed in the second sub-pixel PX2, and a second wavelength conversion layer WCL2 disposed in the third sub-pixel PX3.

The light transmission layer TPL may include a first base resin BRS1 and scatterers SCP disposed in the first base resin BRS1. The light transmission layer TPL may pass the light L1 of the first color incident from the light emitting element ED therethrough while maintaining a wavelength of the light L1 of the first color. The scatterers SCP of the light transmission layer TPL may serve to adjust an emission path of the light emitted through the light transmission layer TPL. The light transmission layer TPL may not include a wavelength conversion material.

The first wavelength conversion layer WCL1 may include a second base resin BRS2, and a first wavelength conversion material WCP1 and the scatterers SCP disposed in the second base resin BRS2. The second wavelength conversion layer WCL2 may include a third base resin BRS3, and a second wavelength conversion material WCP2 and the scatterers SCP disposed in the third base resin BRS3. The first wavelength conversion layer WCL1 and the second wavelength conversion layer WCL2 may convert the wavelength of the light L1 of the first color incident from the light emitting element ED and transmit the light L1 with the converted wavelength therethrough. The scatterers SCP in the first wavelength conversion layer WCL1 and the second wavelength conversion layer WCL2 may increase wavelength conversion efficiency.

The scatterers SCP may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), or the like, and examples of a material of the organic particle may include an acrylic resin, a urethane resin, or the like.

The first to third base resins BRS1, BRS2, and BRS3 may include a light transmitting organic material. For example, the first to third base resins BRS1, BRS2, and BRS3 may include an epoxy resin, an acrylic resin, a cardo resin, or an imide resin. All of the first to third base resins BRS1, BRS2, and BRS3 may be made of a same material, but the disclosure is not limited thereto.

The first wavelength conversion material WCP1 may be a material that converts the light L1 of the first color into the light L2 of the second color, and the second wavelength conversion material WCP2 may be a material that converts the light L1 of the first color into the light L3 of the third color. The first wavelength conversion material WCP1 and the second wavelength conversion material WCP2 may be quantum dots, quantum rods, phosphors, or the like. The quantum dot may include group IV nanocrystals, group II-VI compound nanocrystals, group III-V compound nanocrystals, group IV-VI compound nanocrystals, or a combination thereof.

The light transmission layer TPL, the first wavelength conversion layer WCL1, and the second wavelength conversion layer WCL2 may be spaced apart from each other as being disposed to correspond to the emitting material area EMA, respectively. The separation space may substantially overlap the non-emitting material area NEA, and the separation space may form a valley portion having a lattice shape in plan view.

The light L1 emitted from the light emitting element ED disposed in the first sub-pixel PX1 may be incident on the light transmission layer TPL, the light L1 emitted from the light emitting element ED disposed in the second sub-pixel PX2 may be incident on the first wavelength conversion layer WCL1, and the light L1 emitted from the light emitting element ED disposed in the third sub-pixel PX3 may be incident on the second wavelength conversion layer WCL2. The light incident on the light transmission layer TPL may be transmitted as the light L1 of the same first color without wavelength being converted, the light incident on the first wavelength conversion layer WCL1 may be converted into the light of the second color L2, and the light incident on the second wavelength conversion layer WCL2 may be converted into the light L3 of the third color. Even in case that the respective sub-pixels PXn include the light emitting elements EL emitting light of the a color, the respective sub-pixels PXn may display light of different colors according to an arrangement of the color control structures TPL, WCL1, and WCL2 disposed on an upper side of the light emitting elements EL.

In the embodiments of FIGS. 4 and 5, it is illustrated that the color control structures TPL, WCL1, and WCL2 are formed in a pattern through a photoresist. However, the color control structures TPL, WCL1, and WCL2 are not limited thereto and may be formed through an inkjet-printing process.

A first capping layer CPL1 may be disposed on the color control structures TPL, WCL1, and WCL2. The first capping layer CPL1 may be disposed to cover the color control structures TPL, WCL1, and WCL2 and the second surface of the first insulating layer PAS1. The first capping layer CPL1 may prevent impurities such as moisture or air from permeating from the outside to damage or contaminate the color control structures TPL, WCL1, and WCL2. The first capping layer CPL1 may prevent materials of the color control structures TPL, WCL1, and WCL2 from spreading to other components. The first capping layer CPL1 may be made of an inorganic material. For example, the first capping layer CPL1 may include silicon nitride, aluminum nitride, zirconium nitride, titanium nitride, hafnium nitride, tantalum nitride, silicon oxide, aluminum oxide, titanium oxide, tin oxide, or silicon oxynitride.

A color mixing preventing member MBM may be disposed on the first capping layer CPL1. The color mixing preventing member MBM may be made of a material capable of blocking transmission of light to prevent color mixing from occurring due to light emitted from the color control structures TPL, WCL1, and WCL2 and permeating into adjacent sub-pixels PXn. The color mixing preventing member MBM may be disposed along a boundary between the sub-pixels PXn. For example, the color mixing preventing member MBM may be disposed along the separation space between the color control structures TPL, WCL1, and WCL2 and may be disposed to overlap the non-emitting material area NEA or the first bank BNL of the display layer DL in the thickness direction. The color mixing preventing member MBM may fill the valley portion disposed in the separation space between the color control structures TPL, WCL1, and WCL2. A top surface of the color mixing preventing member MBM may protrude in the thickness direction over top surfaces of the color control structures TPL, WCL1, and WCL2, but the disclosure is not limited thereto.

The color mixing preventing member MBM may include an organic material. The color mixing preventing member MBM may include a light absorbing material that absorbs light in a visible wavelength band. In an embodiment, the color mixing preventing member MBM may include an organic light blocking material.

A light blocking member BM and color filter layers CFL1, CFL2, and CFL3 may be disposed on the color control structures TPL, WCL1, and WCL2 and the color mixing preventing member MBM.

The light blocking member BM may overlap the first bank BNL of the display layer DL in the thickness direction and may be disposed in the non-emitting material area NEA. The light blocking member BM may include an opening exposing the color control structures TPL, WCL1, and WCL2 overlapping the emitting material area EMA or the top surface of the first capping layer CPL1 covering the upper surfaces of the color control structures TPL, WCL1, and WCL2, and may be formed in a lattice shape in plan view. The light blocking member BM may be disposed to overlap a portion of the first bank BNL that spans the boundary between the sub-pixels PXn. For example, the light blocking member BM may be not necessarily disposed to surround only the emitting material area EMA, and may be disposed at the boundary between the sub-pixels PXn where the color filter layers CFL1, CFL2, and CFL3 are disposed, including a portion of the non-emitting material area NEA.

The light blocking member BM may include an organic material. The light blocking member BM may reduce distortion of colors due to reflection of external light by absorbing the external light. In an embodiment, the light blocking member BM may absorb all visible light wavelengths. The light blocking member BM may include a light absorbing material. For example, the light blocking member BM may be made of a material used as a black matrix of the display device 10, and may be made of substantially a same material as the color mixing preventing member MBM.

In another embodiment, the light blocking member BM may absorb light of a specific wavelength of the visible light wavelengths and transmit light of another specific wavelength. For example, the light blocking member BM may include a same material as one of the color filter layers CFL1, CFL2, and CFL3. For example, the light blocking member BM may be made of a same material as the first color filter layer CFL1. In some embodiments, the light blocking member BM may be formed integrally with the first color filter layer CFL1.

The color filter layers CFL1, CFL2, and CFL3 may be disposed on the first capping layer CPL1 exposed through the opening of the light blocking member BM. The color filter layers CFL1, CFL2, and CFL3 may include a first color filter layer CFL1 disposed in the first sub-pixel PX1, a second color filter layer CFL2 disposed in the second sub-pixel PX2, and a third color filter layer CFL3 disposed in the third sub-pixel PX3. Each of the color filter layers CFL1, CFL2, and CFL3 may include a colorant such as a dye or pigment that absorbs a wavelength other than a color wavelength displayed by each of the sub-pixels PXn. The first color filter layer CFL1 may be a blue color filter layer, the second color filter layer CFL2 may be a green color filter layer, and the third color filter layer CFL3 may be a red color filter layer. The light emitted from the light emitting elements ED may pass through the color control structures TPL, WCL1, and WCL2 and may be emitted through the color filter layers CFL1, CFL2, and CFL3.

For example, the light L1 of the first color emitted from the light emitting element layer ED of the first sub-pixel PX1 may pass through the light transmission layer TPL and may be incident on the first color filter layer CFL1 in a state in which a color thereof is not changed. The first base resin BRS1 of the light transmission layer TPL may be made of a transparent material, and some of the light may be transmitted through the first base resin BRS1 and may be incident on the first capping layer CPL1 and the first color filter layer CFL1 disposed on the first base resin BRS1. At least some of the light may be incident on the scatterers SCP disposed in the first base resin BRS1, and may be incident on the first capping layer CPL1 and the first color filter layer CFL1 after the light is scattered. The first color filter layer CFL1 may block transmission of light of other colors except for the light L1 of the first color, and the light L1 of the first color may be displayed in the first sub-pixel PX1.

The light L1 of the first color emitted from the light emitting element ED of the second sub-pixel PX2 may pass through the first wavelength conversion layer WCL1, such that some of the light L1 of the first color is converted into the light L2 of the second color and may be incident on the second color filter layer CFL2. The second base resin BRS2 of the first wavelength conversion layer WCL1 may be made of a transparent material, and some of the light may transmit through the second base resin BRS2. However, at least some of the light may be incident on the scatterers SCP and the first wavelength conversion material WCP1 disposed in the second base resin BRS2, and the light may be scattered and wavelength-converted and be incident on the first capping layer CPL1 and the second color filter layer CFL2 as the light L2 of the second color. The second color filter layer CFL2 may block transmission of light of other colors except for the light L2 of the second color, and the light L2 of the second color may be displayed in the second sub-pixel PX2. Similarly, in the third sub-pixel PX3, the light L1 of the first color emitted from the light emitting element ED may pass through the second wavelength conversion layer WCL2 and the third color filter layer CFL3 and be displayed as the light L3 of the third color. The display device 10 may display light of different colors for each of the sub-pixels PXn even though each of the sub-pixels PXn includes the light emitting element ED emitting light of a same color.

Although it is illustrated in the drawings that the color filter layers CFL1, CFL2, and CFL3 adjacent to each other are disposed to be spaced apart from each other based on the light blocking member BM, the color filter layers CFL1, CFL2, and CFL3 adjacent to each other may at least partially overlap each other on the light blocking member BM.

The color filter layers CFL1, CFL2, and CFL3 may be disposed to cover the emitting material area EMA in each of the sub-pixels PXn. Although it is illustrated in the drawings that the color filter layers CFL1, CFL2, and CFL3 are disposed for each of the sub-pixels PXn to form an island-shaped pattern, the disclosure is not limited thereto. The color filter layers CFL1, CFL2, and CFL3 may form a linear pattern across the entire surface of the display area DPA. The light blocking member BM may have a width less than that of the first bank BNL, and the color filter layers CFL1, CFL2, and CFL3 may partially overlap the first bank BNL in the thickness direction.

A second capping layer CPL2 may be disposed on the color filter layers CFL1, CFL2, and CFL3 and the light blocking member BM. The second capping layer CPL2 may prevent impurities such as moisture or air from permeating from the outside to damage or contaminate the color filter layers CFL1, CFL2, and CFL3. The second capping layer CPL2 may include the a material as the first capping layer CPL1, but the disclosure is not limited thereto.

The light emitted from each light emitting element ED may be the light L1 of the same first color. The light emitting element ED may emit light from both ends which are in contact with the respective electrodes CNE1 and CNE2, and the light may travel in a random direction. The light emitting elements ED may be disposed in an area surrounded by the first bank BNL, and the color control structures TPL, WCL1, and WLC2 may be disposed on the first insulating layer PAS1 in a direction opposite to the light emitting elements ED. The light emitting element ED and the circuit layer may be formed on the first surface of the first insulating layer PAS1 during the manufacturing process of the display device 10, and the color control structures TPL, WCL1, and WLC2 on the second surface of the first insulating layer PAS1 may be formed using a separate substrate. The display device 10 may include only one first base substrate BS, and may have a structure in which the circuit layer, the light emitting elements ED, the first insulating layer PAS1, and the color control structures TPL, WCL1, and WLC2 are sequentially formed on the first base substrate BS.

The color control structures TPL, WCL1, and WLC2 may be spaced apart from the light emitting elements ED by a thickness of the first insulating layer PAS1, so that the color control structures TPL, WCL1, and WLC2 may be disposed closer to the light emitting elements ED than the case that the color control structures TPL, WCL1, and WLC2 are disposed on the first bank BNL. The first insulating layer PAS1 may have a thickness less than that of the first base substrate BS, and most of the light emitted from the light emitting elements ED may be directly incident on the color control structures TPL, WCL1, and WCL2 without being reflected or absorbed by other members. Even if separate members for reflecting the light emitted from both ends of the light emitting element ED to the second surface of the first insulating layer PAS1 are omitted from the display device 10, the light may travel to the color control structures TPL, WCL1, and WCL2. As the display device 10 includes only one first base substrate BS and the light emitting element layer EL and the color control structures TPL, WCL1, and WCL2 are disposed adjacent to each other with the first insulating layer PAS1 interposed therebetween, light emitting efficiency and color matching rate of the display device 10 may be improved.

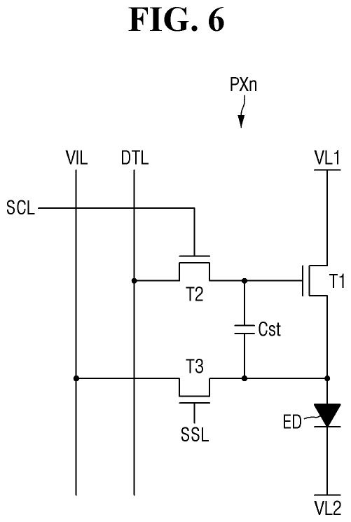

FIG. 6 is a schematic diagram of an equivalent circuit of one sub-pixel according to an embodiment.

Referring to FIG. 6, each sub-pixel PXn of the display device 10 according to an embodiment may include three transistors T1, T2, and T3 and one storage capacitor Cst, in addition to the light emitting element ED.

The light emitting element ED may emit light according to a current supplied through the first transistor T1. The light emitting element ED may be electrically connected to the first transistor T1 and the second voltage line VL2 through the first electrode CNE1 and the second electrode CNE2. The light emitting element ED may emit light in a specific wavelength range by electrical signals transmitted from the first electrode CNE1 and the second electrode CNE2.

An electrode of the light emitting element ED may be connected to a source electrode of the first transistor T1, and another electrode of the light emitting element ED may be connected to a second voltage line VL2 to which a low potential voltage (hereinafter, referred to as a second power supply voltage) lower than a high potential voltage (hereinafter, referred to as a first power supply voltage) of a first voltage line VL1 is supplied.

The first transistor T1 may adjust a current flowing from the first voltage line VL1 to which the first power supply voltage is supplied to the light emitting element ED according to a voltage difference between a gate electrode and the source electrode thereof. For example, the first transistor T1 may be a driving transistor for driving the light emitting element ED. The gate electrode of the first transistor T1 may be connected to a source electrode of a second transistor T2, the source electrode of the first transistor T1 may be connected to a first electrode of the light emitting element ED, and a drain electrode of the first transistor T1 may be connected to the first voltage line VL1 to which the first power supply voltage is applied.

The second transistor T2 may be turned on by a scan signal of a first scan line SCL to connect a data line DTL to the gate electrode of the first transistor T1. A gate electrode of the second transistor T2 may be connected to the first scan line SCL, the source electrode of the second transistor T2 may be connected to the gate electrode of the first transistor T1, and a drain electrode of the second transistor T2 may be connected to the data line DTL.

A third transistor T3 may be turned on by a second scan signal of a second scan line SSL to connect an initialization voltage line VIL to an electrode of the light emitting element ED. A gate electrode of the third transistor T3 may be connected to the second scan line SSL, a drain electrode of the third transistor T3 may be connected to the initialization voltage line VIL, and a source electrode of the third transistor T3 may be connected to an electrode of the light emitting element ED or the source electrode of the first transistor T1.

The source electrode and the drain electrode of each of the transistors T1, T2, and T3 are not limited to those described above, and may be vice versa. Each of the transistors T1, T2, and T3 may be formed as a thin film transistor. It is described in FIG. 6 that each of the transistors T1, T2, and T3 is formed as an N-type metal oxide semiconductor field effect transistor (MOSFET), but the disclosure is not limited thereto. For example, each of the transistors T1, T2, and T3 may be formed as a P-type MOSFET, or some of the transistors T1, T2, and T3 may be formed as an N-type MOSFET and another one of the transistors T1, T2, and T3 may be formed as a P-type MOSFET.

The storage capacitor Cst may be formed between the gate electrode and the source electrode of the first transistor T1. The storage capacitor Cst may store a difference in voltage between a gate voltage and a source voltage of the first transistor T1.

FIG. 7 is a schematic view of a light emitting element according to an embodiment.

The light emitting element ED may be a light emitting diode. For example, the light emitting element ED may be an inorganic light emitting diode having a size of a nano-meter to a micro-meter and made of an inorganic material. The inorganic light emitting diode may be aligned between two electrodes in which polarities are formed in case that an electric field is formed in a specific direction between the two electrodes facing each other. The light emitting element ED may be aligned between the two electrodes by the electric field formed on the two electrodes.

The light emitting element ED according to an embodiment may have a shape extending in a direction. The light emitting element ED may have a shape such as a rod, a wire, or a tube. In an embodiment, the light emitting element ED may have a cylindrical shape or a rod shape. However, the shape of the light emitting element ED is not limited thereto and the light emitting element ED may have various shapes. For example, the light emitting element ED may have a polygonal prismatic shape such as a cubic shape, a rectangular parallelepiped shape, or a hexagonal prismatic shape or have a shape extending in a direction and having a partially inclined outer surface. Multiple semiconductors included in a light emitting element ED to be described later may have a structure in which they are sequentially disposed or stacked along the direction.

The light emitting element ED may include a semiconductor layer doped with a conductivity type (e.g., p-type or n-type) impurity. The semiconductor layer may receive an electrical signal applied from an external power source to emit light in a specific wavelength band.

Referring to FIG. 7, the light emitting element ED may include a first semiconductor layer 31, a second semiconductor layer 32, a light emitting layer 36, an electrode layer 37, and an insulating film 38.

The first semiconductor layer 31 may be an n-type semiconductor. For example, in case that the light emitting element ED emits light in a blue wavelength band, the first semiconductor layer 31 may include a semiconductor material having a chemical formula of AlₓGa_{y}In_{1-x-y}N (0≤x≤1, 0≤y≤1, and 0≤x+y≤1). For example, the semiconductor material may be at least one of AlGaInN, GaN, AlGaN, InGaN, AlN, and InN doped with an n-type. The first semiconductor layer 31 may be doped with an n-type dopant, which may be, for example, Si, Ge, Sn, or the like. In an embodiment, the first semiconductor layer 31 may be n-GaN doped with n-type Si. A length of the first semiconductor layer 31 may be in the range of about 1.5 μm to about 5 μm, but the disclosure is not limited thereto.

The second semiconductor layer 32 may be disposed on a light emitting layer 36 to be described later. The second semiconductor layer 32 may be a p-type semiconductor, and for example, in case that the light emitting element ED emits light in a blue or green wavelength band, the second semiconductor layer 32 may include a semiconductor material having a chemical formula of AlₓGa_{y}In_{1-x-y}N (0≤x≤1, 0≤y≤1, and 0≤x+y≤1). For example, the semiconductor material of the second semiconductor layer 32 may be at least one of AlGaInN, GaN, AlGaN, InGaN, AlN, and InN doped with a p-type. The second semiconductor layer 32 may be doped with a p-type dopant, which may be, for example, Mg, Zn, Ca, Se, Ba, or the like. In an embodiment, the second semiconductor layer 32 may be p-GaN doped with p-type Mg. A length of the second semiconductor layer 32 may be in the range of about 0.05 μm to about 0.10 μm, but the disclosure is not limited thereto.

It is illustrated in the drawings that each of the first semiconductor layer 31 and the second semiconductor layer 32 are configured as one layer, but the disclosure is not limited thereto. According to some embodiments, the first semiconductor layer 31 and the second semiconductor layer 32 may further include a larger number of layers, for example, a clad layer or a tensile strain barrier reducing (TSBR) layer, according to a material of the light emitting layer 36.

The light emitting layer 36 may be disposed between the first semiconductor layer 31 and the second semiconductor layer 32. The light emitting layer 36 may include a material having a single or multiple quantum well structure. In case that the light emitting layer 36 includes a material having multiple quantum well structure, the light emitting layer 36 may have a structure in which multiple quantum layers and well layers are alternately stacked each other. For example, in case that the light emitting layer 36 emits light in a blue wavelength band, the light emitting layer 36 may include a material such as AlGaN or AlGaInN. For example, in case that the light emitting layer 36 has the multiple quantum well structure, for example, the structure in which the quantum layer and the well layer are alternately stacked each other, the quantum layer may include a material such as AlGaN or AlGaInN, and the well layer may include a material such as GaN or AlInN. In an embodiment, the light emitting layer 36 may include AlGaInN as a quantum layer and AlInN as a well layer to emit blue light having a central wavelength band in a range of about 450 nm to about 495 nm as described above.

However, the disclosure is not limited thereto, and the light emitting layer 36 may have a structure in which a type of semiconductor material having a large band gap energy and a semiconductor material having a small band gap energy are alternately stacked each other, and may include Group III to Group V semiconductor materials depending on a wavelength band of emitted light. The light emitted by the light emitting layer 36 is not limited to the light in the blue wavelength band, and in some embodiments, the light emitting layer 36 may also emit light in red or green wavelength bands. A length of the light emitting layer 36 may be in the range of about 0.05 μm to about 0.10 μm, but the disclosure is not limited thereto.

The light emitted from the light emitting layer 36 may be emitted to an outer surface of the light emitting element ED in a length direction, and also to both side surfaces of the light emitting element ED. Directivity of the light emitted from the light emitting layer 36 is not limited to one direction.

The electrode layer 37 may be an ohmic contact electrode. However, the disclosure is not limited thereto, and the electrode layer 37 may be a Schottky contact electrode. The light emitting element ED may include at least one electrode layer 37. Although it is illustrated in FIG. 7 that the light emitting element ED includes one electrode layer 37, the disclosure is not limited thereto. In some embodiments, the light emitting element ED may include a larger number of electrode layers 37, or may be omitted. The description of the light emitting element ED to be described later may be equally applied even if the number of electrode layers 37 is changed or the light emitting element ED includes another structure.

The electrode layer 37 may decrease resistance between the light emitting element ED and the electrode or the contact electrode in case that the light emitting element ED is electrically connected to the electrode or the contact electrode in the display device 10 according to an embodiment. The electrode layer 37 may include a conductive metal. For example, the electrode layer 37 may include at least one of aluminum (Al), titanium (Ti), indium (In), gold (Au), silver (Ag), indium tin oxide (ITO), indium zinc oxide (IZO), and indium tin zinc oxide (ITZO). The electrode layer 37 may include a semiconductor material doped with an n-type or a p-type. However, the disclosure is not limited thereto.

The insulating film 38 may be disposed to surround outer surfaces of the semiconductor layers and electrode layers described above. In an embodiment, the insulating film 38 may be disposed to surround at least an outer surface of the light emitting layer 36, and may extend in a direction in which the light emitting element ED extends. The insulating film 38 may perform a function of protecting the members. For example, the insulating film 38 may be formed to surround side surface portions of the members, but may be formed to expose both ends of the light emitting element ED in the length direction.

Although it is illustrated in the drawings that the insulating film 38 is formed to extend in the length direction of the light emitting element ED to cover side surfaces of the first semiconductor layer 31 to the electrode layer 37, the disclosure is not limited thereto. The insulating film 38 may cover only outer surfaces of some semiconductor layers, including the light emitting layer 36 or cover a portion of the side surface of the electrode layer 37 to partially expose the side surface of the electrode layer 37. The insulating film 38 may be formed so that a top surface thereof is rounded in cross section in an area adjacent to at least one end of the light emitting element ED. A thickness of the insulating film 38 may be in the range of about 10 nm to about 1.0 μm, but the disclosure is not limited thereto. For example, the thickness of the insulating film 38 may be about 40 nm.

The insulating film 38 may include a material having insulating properties, such as silicon oxide (SiOₓ), silicon nitride (SiNₓ), silicon oxynitride (SiOₓN_{y}), aluminum nitride (AlNₓ), and aluminum oxide (AlOₓ). Accordingly, an electrical short circuit that may occur in case that the light emitting layer 36 is in direct contact with an electrode through which an electrical signal is transmitted to the light emitting element ED may be prevented. The insulating film 38 may protect the outer surface of the light emitting element ED as well as the light emitting layer 36, and may thus prevent a decrease in light emission efficiency.

In some embodiments, an outer surface of the insulating film 38 may be surface-treated. The light emitting elements ED may be jetted and be aligned on the electrode in a state of being dispersed in an ink. In order to maintain a state in which the light emitting elements ED are dispersed without being clustered with other adjacent light emitting elements ED in the ink, a hydrophobic or hydrophilic treatment may be performed on a surface of the insulating film 38.

The light emitting element ED may have a length h in a range of about 1 μm to about 10 μm. For example, the length h of the light emitting element ED may be in a range of about 2 μm to about 6 μm. For example, the length h of the light emitting element ED may be in a range of about 3 μm to about 5 μm. A diameter of the light emitting element ED may be in the range of about 30 nm to about 700 nm, and an aspect ratio of the light emitting element ED may be in a range of about 1.2 to about 100. However, the disclosure is not limited thereto, and the light emitting elements ED included in the display device 10 may have different diameters according to a difference in composition of the light emitting layer 36. For example, the diameter of the light emitting element ED may be about 500 nm.

A manufacturing method for a display device 10 according to an embodiment may include preparing a separate alignment substrate to form light emitting elements ED, electrodes CNE1 and CNE2, and a circuit layer. A display layer DL of the display device 10 may be formed by manufacturing a display element substrate on which the light emitting elements ED, the electrodes CNE1 and CNE2, and the circuit layer are formed using an alignment substrate that is different from the first base substrate BS, bonding the display element substrate to the first base substrate BS, and removing the alignment substrate. The display device 10 may be manufactured by performing a process of forming the color control layer CL on the display layer DL. In the manufacturing method for the display device 10 using the alignment substrate, the light emitting elements ED and the color control structures TPL, WCL1, and WCL2 disposed on the first surface and the second surface of the first insulating layer PAS1, respectively, may be disposed adjacent to each other.

Hereinafter, a manufacturing process of the display device 10 according to an embodiment will be described with further reference to other drawings.

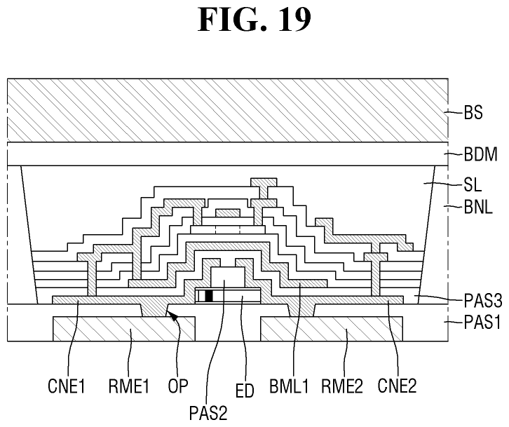

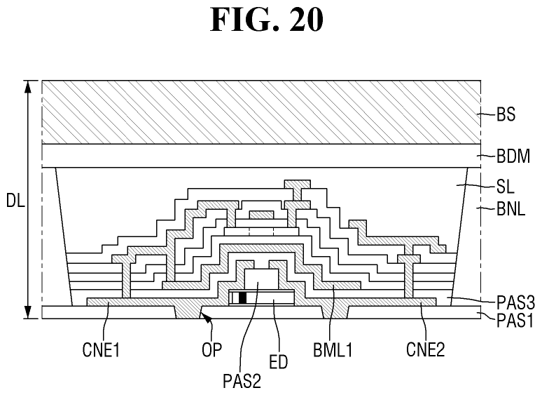

FIGS. 8 to 20 are views sequentially illustrating steps in a manufacturing process of a display element layer of a display device according to an embodiment.

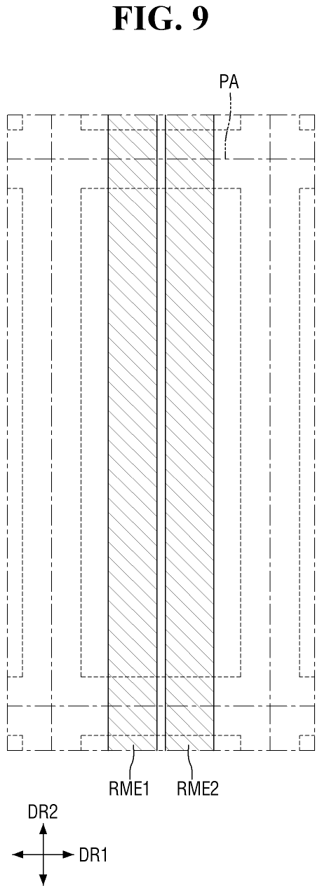

First, referring to FIGS. 8 and 9, an alignment substrate AS including a target substrate SUB, an auxiliary layer PIL disposed on the target substrate SUB, and multiple alignment electrodes RME1 and RME2 disposed on the auxiliary layer PIL may be prepared. In FIG. 8, the target substrate SUB of the alignment substrate AS may include substantially the same material as the first base substrate BS. Multiple pixel areas PA corresponding to the sub-pixels PXn of the first base substrate BS may be defined on the target substrate SUB.

The auxiliary layer PIL may be disposed on an entire area of the target substrate SUB. The auxiliary layer PIL may provide a space in which the alignment electrodes RME1 and RME2 may be disposed. As the auxiliary layer PIL is disposed, the alignment electrodes RME1 and RME2 of the target substrate SUB may be readily separated in a subsequent process. The auxiliary layer PIL may include polyimide, but the disclosure is not limited thereto.

The alignment electrodes RME1 and RME2 may extend in the second direction DR2 within the pixel area PA defined on the target substrate SUB. A first alignment electrode RME1 and a second alignment electrode RME2 may be disposed to be spaced apart from and opposed to each other in the first direction DR1, and may extend in the second direction DR2 and may be disposed across the pixel areas PA. Although not illustrated in the drawings, the first alignment electrode RME1 and the second alignment electrode RME2 may be connected to a pad portion disposed on an outer portion of the target substrate SUB, and the pad portion may be connected to an external device to be applied with an alignment signal. In case that the alignment signal is applied to the first alignment electrode RME1 and the second alignment electrode RME2, an electric field E may be generated between the first alignment electrode RME1 and the second alignment electrode RME2 due to a voltage difference between the alignment signals. Each of the alignment electrodes RME1 and RME2 may include a metal having high conductivity.

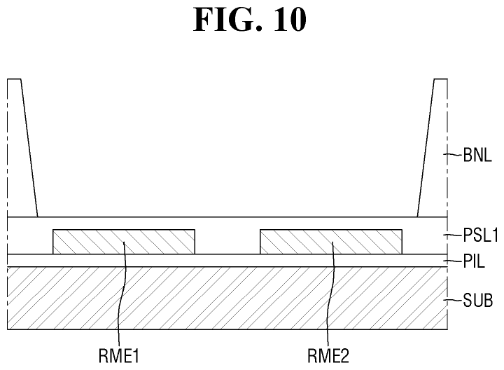

Referring to FIG. 10, a first insulating material layer PSL1 may be formed on the alignment substrate AS, and a first bank BNL may be formed on the first insulating material layer PSL1. The first insulating material layer PSL1 may include substantially a same material as the first insulating layer PAS1 and may be partially removed in a subsequent process to form a first insulating layer PAS1. Since the first insulating material layer PSL1 is formed to be thicker than the first insulating layer PAS1, the first insulating material layer PSL1 may have a certain thickness even if a portion of the first insulating material layer PSL1 is removed in the process of removing the alignment substrate AS. The first insulating material layer PSL1 may be disposed on an entire area of the auxiliary layer PIL to cover the alignment electrodes RME1 and RME2. The first insulating material layer PSL1 may prevent the light emitting elements ED from being in direct contact with the alignment electrodes RME1 and RME2 while forming an area where the light emitting elements ED formed in a subsequent process are disposed.

The first bank BNL may have the structure described above. The first bank BNL may have a shape protruding from a top surface of the first insulating material layer PSL1 and may be disposed in a lattice shape across a boundary between the pixel areas PA. Based on the arrangement of the first bank BNL, the sub-pixels PXn of the display layer DL may be distinguished. The first bank BNL may prevent ink including the light emitting elements ED from overflowing to other pixel areas PA in the process of arranging the light emitting elements ED.

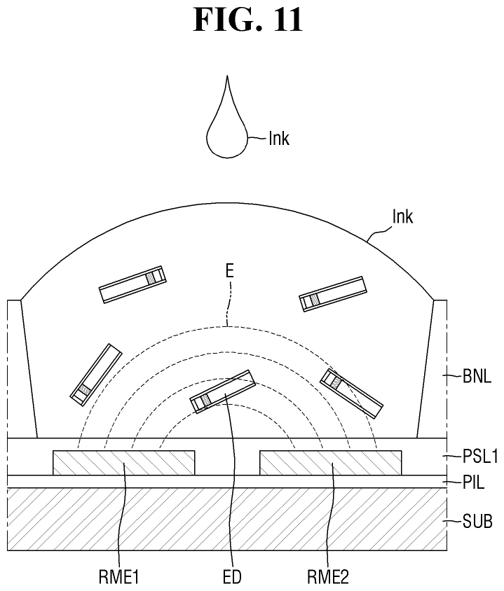

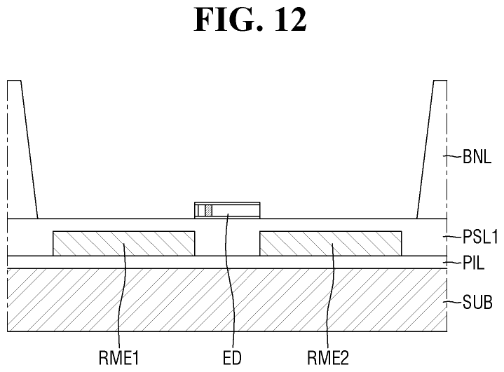

Referring to FIGS. 11 and 12, the ink including the light emitting elements ED may be jetted into each pixel area PA, an electric field E may be generated on the alignment electrodes RME1 and RME2, and the light emitting elements ED may be disposed on the first insulating material layer PSL1. In an embodiment, the light emitting elements ED may be prepared in a state of being dispersed in the ink and may be jetted into each pixel area PA through a printing process using an inkjet printing device. The ink jetted through the inkjet printing device may be seated in an area surrounded by the first bank BNL.

After the ink including the light emitting elements ED is jetted, the alignment signal may be applied to each of the alignment electrodes RME1 and RME2, and the light emitting elements ED may be disposed on the first insulating material layer PSL1. In case that the alignment signal is applied to each of the alignment electrodes RME1 and RME2, an electric field E may be generated between the alignment electrodes RME1 and RME2. The light emitting elements ED dispersed in the ink may have a dipole moment by including semiconductor layers doped with different conductivity types. The light emitting elements ED placed in the electric field E may receive a dielectrophoretic force, and may be seated on the first insulating material layer PSL1 while the alignment direction and position thereof are changed. The light emitting element ED may be disposed such that an end thereof is placed on the first alignment electrode RME1 and another end thereof is placed on the second alignment electrode RME2. A length of the light emitting element ED may be greater than a gap between the first alignment electrode RME1 and the second alignment electrode RME2, and each end thereof may be placed on the alignment electrodes RME1 and RME2.

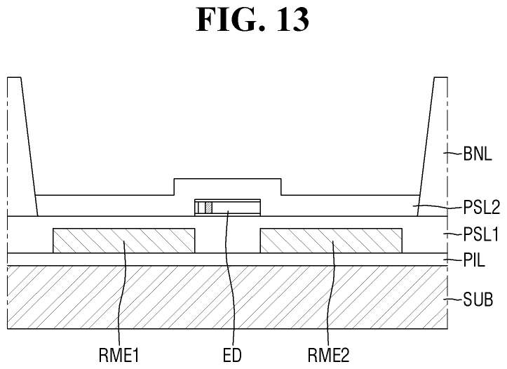

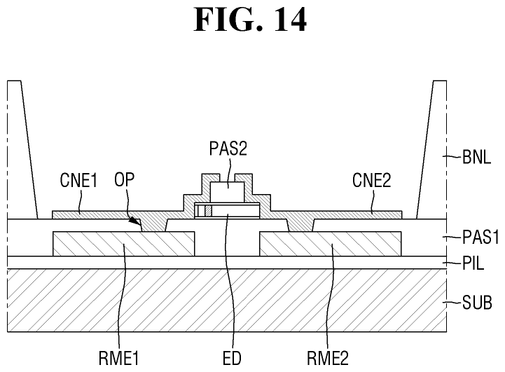

Referring to FIGS. 13 and 14, the light emitting elements ED and the electrodes CNE1 and CNE2 may be arranged by forming a second insulating layer PAS2 on the light emitting elements ED and forming the electrodes CNE1 and CNE2 to be in contact with each end of the light emitting element ED. The second insulating layer PAS2 may be formed through a process of forming a second insulating material layer PSL2 disposed on an entire area of the first insulating material layer PSL1 to cover the light emitting elements ED and partially removing the second insulating material layer PSL2 so that both ends the light emitting element ED are exposed. The second insulating material layer PSL2 may fix positions at which the light emitting elements ED are disposed on the alignment electrodes RME1 and RME2.

After the position of the light emitting element ED is fixed, both ends of the light emitting element ED and portions of the top surfaces of the alignment electrodes RME1 and RME2 may be exposed by partially removing the first insulating material layer PSL1 and the second insulating material layer PSL2. The first insulating material layer PSL1 may include openings OP formed to expose portions of the top surfaces of the alignment electrodes RME1 and RME2, and the second insulating material layer PSL2 may be partially removed to expose both ends of the light emitting element ED. After the process, the first insulating material layer PSL1 and the second insulating material layer PSL2 may form the first insulating layer PAS1 and the second insulating layer PAS2, respectively.

A first electrode CNE1 and a second electrode CNE2 may be formed on the first insulating layer PAS1. The first electrode CNE1 and the second electrode CNE2 may be in contact with each end of the light emitting element ED, respectively, and ends of the first electrode CNE1 and the second electrode CNE2 may be disposed to be spaced apart from each other on the second insulating layer PAS2. The first electrode CNE1 may be directly disposed on the first insulating layer PAS1 and may be in direct contact with the first alignment electrode RME1 through the opening OP exposing the first alignment electrode RME1. The second electrode CNE2 may be directly disposed on the first insulating layer PAS1 and may be in direct contact with the second alignment electrode RME2 through the opening OP exposing the second alignment electrode RME2. The electrical signals applied to the alignment electrodes RME1 and RME2 may be transferred to the light emitting element ED through the electrodes CNE1 and CNE2.

According to an embodiment, the manufacturing process of the display device 10 may include a process of checking light emitting defects of the light emitting elements ED and a repair process of the light emitting defects, after disposing the light emitting elements ED on the first insulating layer PAS1 and forming the electrodes CNE1 and CNE2. It may be checked whether the light emitting elements ED of each pixel area PA emit light by applying an electrical signal for driving the light emitting elements ED through the alignment electrodes RME1 and RME2. In case that the light emitting elements ED do not emit light, the non-emissive light emitting element may be removed or the connection with the electrodes CNE1 and CNE2 may be repaired. For example, an end of the light emitting elements ED may not be in contact with the electrodes CNE1 and CNE2, or the first electrode CNE1 and the second electrode CNE2 may be directly connected to each other, so that the light emitting element ED of the corresponding pixel area PA may be shorted. Since the pixel area PA where the light emitting element ED is shorted may remain as a defective sub-pixel PXn in the display device 10, a process of repairing the short of the light emitting element ED may be performed after forming the light emitting element ED and the electrodes CNE1 and CNE2.

The alignment substrate AS may provide a space in which the first insulating layer PAS1 and the light emitting element ED disposed on the first surface of the first insulating layer PAS1 are disposed, and at the same time, may be subjected to a repair process of supplementing defects that may occur in the light emitting element ED and the electrodes CNE1 and CNE2. In case that the electrodes CNE1 and CNE2 are shorted in a pixel area PA as described above, a process of removing the shorted portion by irradiating a laser or the like may be performed. Since the alignment substrate AS is not finally included in the display device 10 and only the first insulating layer PAS1 is disposed on a lower side of the light emitting element ED, it may not matter if the alignment substrate AS is partially damaged during the repair process.

Since the alignment electrodes RME1 and RME2 are not included in the display device 10 and are removed, structures of the light emitting elements ED and the electrodes CNE1 and CNE2 may be freely designed regardless of structures of the alignment electrodes RME1 and RME2. Even in case that an area occupied by each pixel area PA is small, as long as the space in which the light emitting elements ED and the electrodes CNE1 and CNE2 are disposed is secured in each pixel area PA, the structures of the alignment electrodes RME1 and RME2 may be designed in relation only to the arrangement positions of the light emitting elements ED. Since the manufacturing method for the display device 10 uses a separate alignment substrate AS for disposing the light emitting elements ED, a process of repairing the light emitting element ED or a structural design thereof may be free.

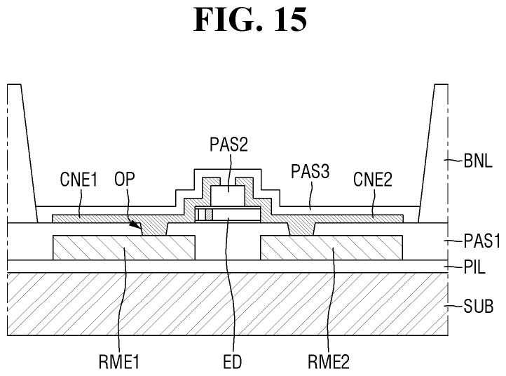

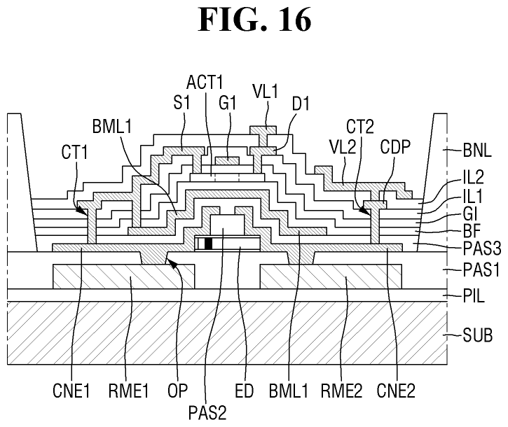

Referring to FIGS. 15 and 16, a third insulating layer PAS3 covering the light emitting element ED and the electrodes CNE1 and CNE2 may be formed, and a circuit layer may be formed thereon. As described above, the circuit layer may include the lower metal layer BML1, the active layer ACL1, the first gate conductive layer, the first data conductive layer, the second data conductive layer, the buffer layer BF, the first gate insulating layer GI, the first interlayer insulation a layer ILL and the second interlayer insulating layer IL2. A description of the structure and arrangement thereof is the same as that described above. For example, the lower metal layer BML1 may be disposed to cover at least the light emitting elements ED in the thickness direction.

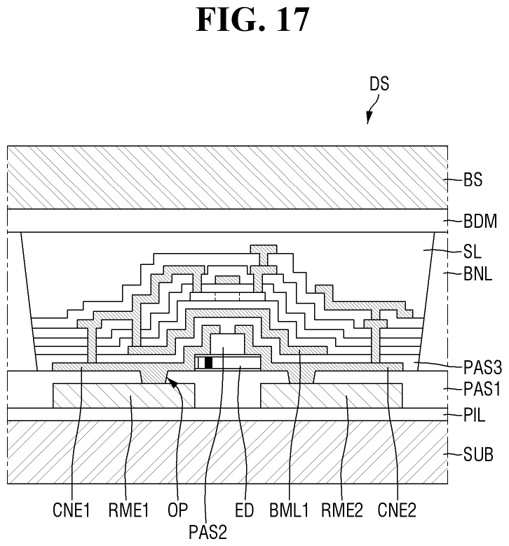

Referring to FIG. 17, a first planarization layer SL may be formed on the circuit layer, and a display element substrate DS may be formed by bonding the first planarization layer SL to the first base substrate BS by a bonding agent BDM. The display element substrate DS may include the light emitting element ED, the electrodes CNE1 and CNE2, the circuit layer, and the first bank BNL disposed between the alignment substrate AS and the first base substrate BS. The display element substrate DS may be a structure formed before performing a subsequent process of forming the color control layer CL, including the display layer DL of the display device 10. Since the alignment substrate AS is removed and the first base substrate BS becomes the substrate of the display device 10, the first base substrate BS and the alignment substrate AS may not need to be aligned with each other. The first base substrate BS may be bonded to the circuit layer by the bonding agent BDM in a state in which a specific area is not divided. Even in case that the first base substrate BS and the alignment substrate AS are not aligned with each other, areas corresponding to the pixel areas PA of the alignment substrate AS may correspond to the sub-pixels PXn of the first base substrate BS.

A process of removing the alignment substrate AS from the display element substrate DS may be performed.

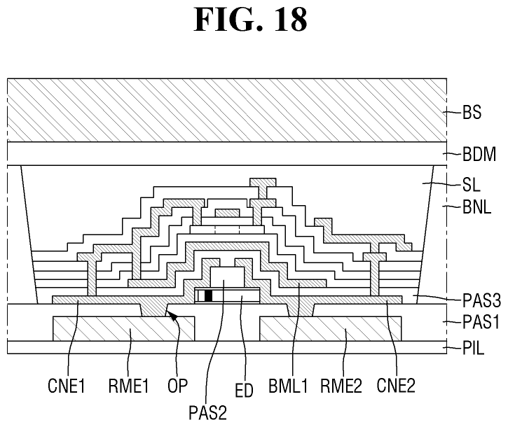

Referring to FIGS. 18 to 20, a process of separating the target substrate SUB from the display element substrate DS and removing the auxiliary layer PIL and the alignment electrodes RME1 and RME2 may be performed. For example, the target substrate SUB may be readily removed through a detachment process from the auxiliary layer PIL. The auxiliary layer PIL may be removed through a dry etching process or a polishing process, and the alignment electrodes RME1 and RME2 may be removed by an etching process using an etchant. Some of the alignment electrodes RME1 and RME2 may be removed during the process of removing the auxiliary layer PIL, but even in case that the alignment electrodes RME1 and RME2 are removed, the first insulating layer PAS1 may ultimately remain.

As the alignment electrodes RME1 and RME2 include materials different from those of the respective electrodes CNE1 and CNE2, the electrodes CNE1 and CNE2 may hardly be removed in the process of removing the alignment electrodes RME1 and RME2 using the etchant. Accordingly, the display device 10 may be disposed in a state in which the electrodes CNE1 and CNE2 remain in the openings OP of the first insulating layer PAS1. In the process of removing the alignment electrodes RME1 and RME2, a process of planarizing the second surface of the first insulating layer PAS1 may be further performed, but the disclosure is not limited thereto. Through the above-described process, the display layer DL including the circuit layer, the light emitting elements ED, and the electrodes CNE1 and CNE2 disposed on the first base substrate BS may be manufactured. A color control layer CL may be formed by disposing the color control structures TPL, WCL1, and WCL2 and the color filter layers CFL1, CFL2, and CFL3 on the second surface of the first insulating layer PAS1 facing the first base substrate BS.

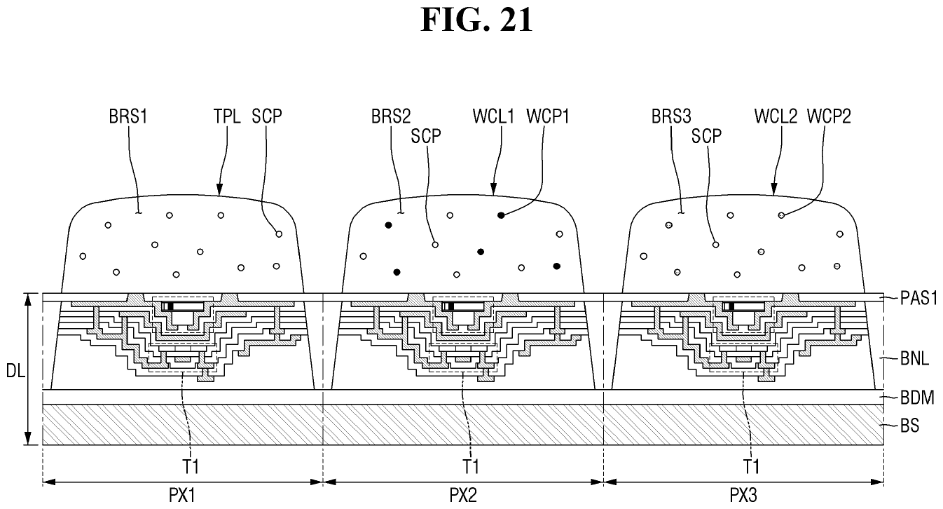

FIGS. 21 to 25 are views sequentially illustrating steps in a manufacturing process of a color control layer of a display device according to an embodiment.

Referring to FIG. 21, color control structures TPL, WCL1, and WCL2 may be formed on the second surface of the first insulating layer PAS1 in an area corresponding to the emitting material area EMA. Multiple sub-pixels PXn corresponding to multiple pixel areas PA of the alignment substrate AS may be defined in the first base substrate BS. A light transmission layer TPL may be formed in a first sub-pixel PX1, a first wavelength conversion layer WCL1 may be formed in a second sub-pixel PX2, and a second wavelength conversion layer WCL2 may be formed in a third sub-pixel PX3.

A process of forming the color control structures TPL, WCL1, and WCL2 is not particularly limited. In an embodiment, the color control structures TPL, WCL1, and WCL2 may be formed through a photoresist process or an inkjet printing process.

For example, in case that the color control structures TPL, WCL1, and WCL2 are formed by a photoresist process, the color control structures TPL, WCL1, and WCL2 may be formed by applying base resins BRS1, BRS2, and BRS3 in which scatterers SCP or wavelength conversion materials WCP1 and WCP2 are dispersed in the area surrounded by the first bank BNL, and curing the base resins BRS1, BRS2, and BRS3. Each of the base resins BRS1, BRS2, and BRS3 including different scatterers SCP or wavelength conversion materials WCP1 and WCP2 may be applied to an area corresponding to each of the sub-pixels PXn on the second surface of the first insulating layer PAS1, and may form different color control structures TPL, WCL1, and WCL2 for each of the sub-pixels PXn.

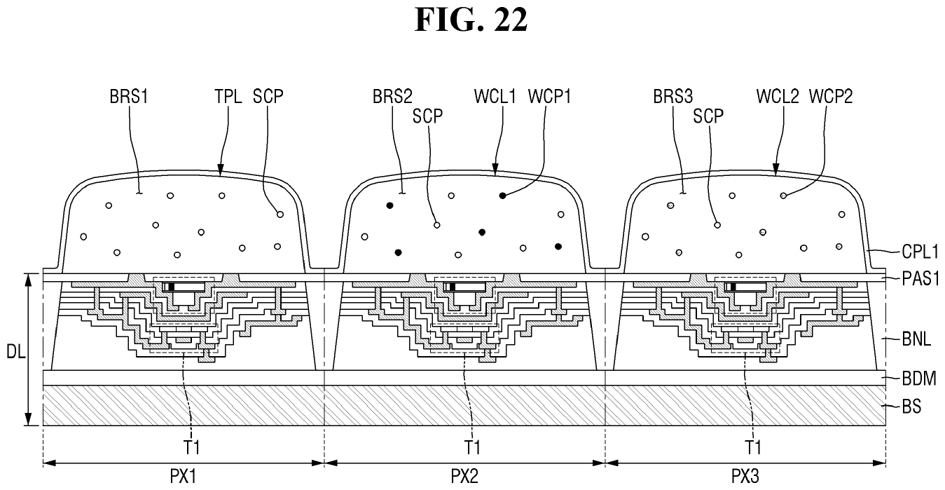

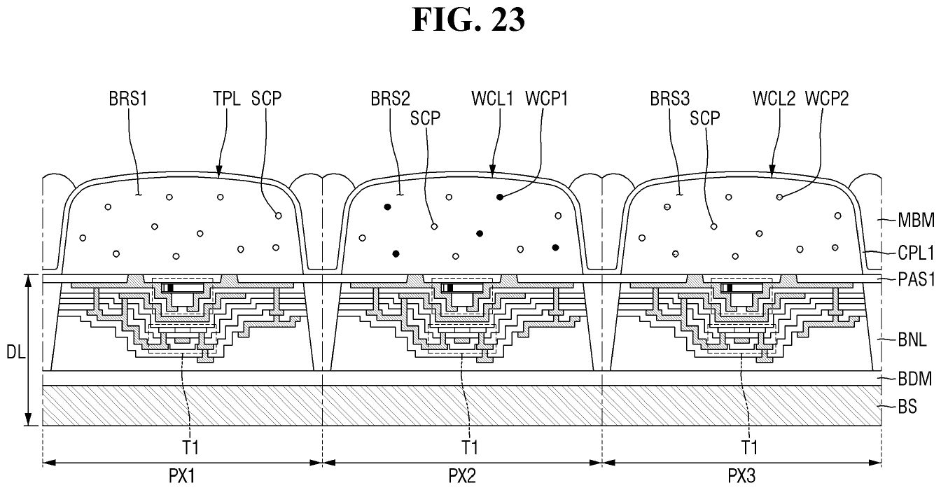

Referring to FIGS. 22 and 23, a first capping layer CPL1 may be formed on the color control structures TPL, WCL1, and WCL2, and a color mixing preventing member MBM may be formed in a space in which the color control structures TPL, WCL1, and WCL2 are spaced apart from each other on the first capping layer CPL1. The first capping layer CPL1 may be disposed to surround the color control structures TPL, WCL1, and WCL2 disposed to correspond to each of the sub-pixels PXn. The color mixing preventing member MBM may be disposed within a valley area between the color control structures TPL, WCL1, and WCL2.

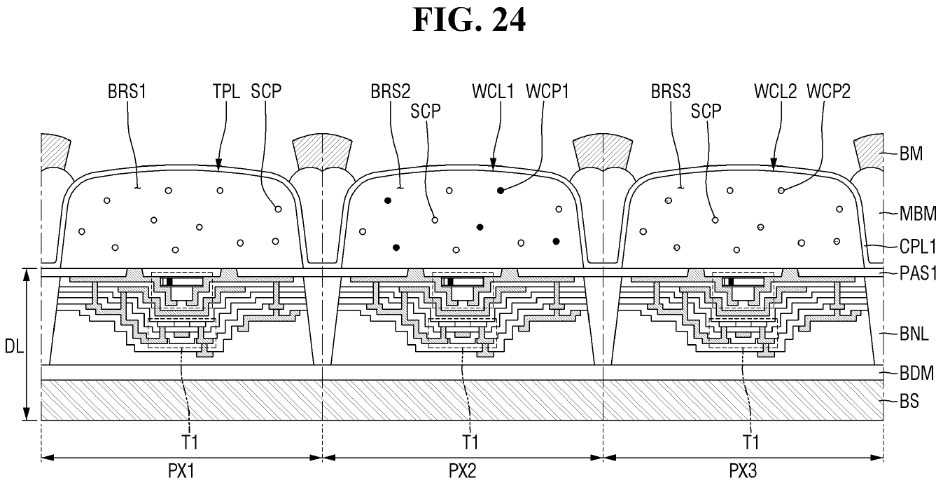

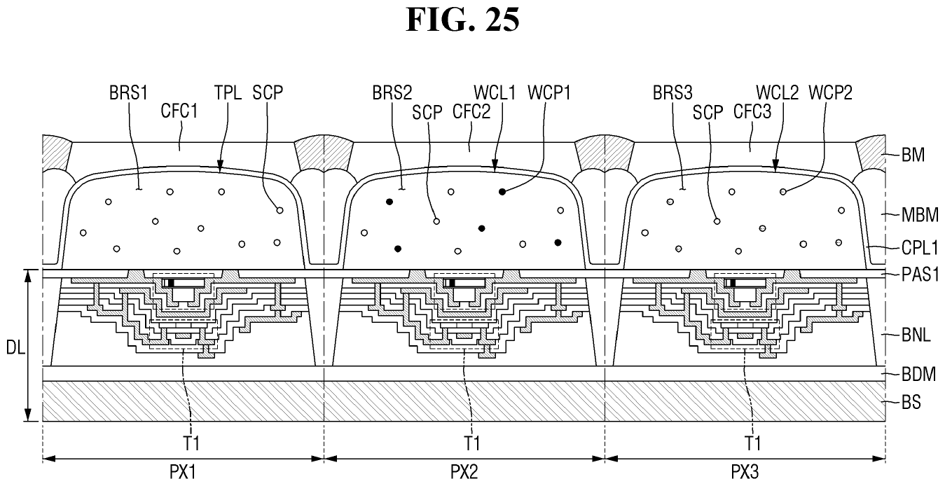

Referring to FIGS. 24 and 25, a light blocking member BM may be formed on the color mixing preventing member MBM, and multiple color filter layers CFL1, CFL2, and CFL3 may be formed on the first capping layer CPL1 exposed without the light blocking members BM disposed thereon. In an embodiment, the color filter layers CFL1, CFL2, and CFL3 may be formed by applying a photosensitive organic material containing a colorant of a specific color, and exposing and developing the photosensitive organic material. For example, the first color filter layer CFL1 may be formed by applying a photosensitive organic material containing a colorant of a blue color, and exposing and developing the photosensitive organic material, the second color filter layer CFL2 may be formed by applying a photosensitive organic material containing a colorant of a green color, and exposing and developing the photosensitive organic material, and the third color filter layer CFL3 may be formed by applying a photosensitive organic material containing a colorant of a red color, and exposing and developing the photosensitive organic material. However, the disclosure is not limited thereto.

Although not illustrated in the drawings, the display device 10 may be manufactured by forming a second capping layer CPL2 covering the light blocking member BM and the color filter layers CFL1, CFL2, and CFL3. Through the above-described process, the display device 10 including the first base substrate BS and having the circuit layer, the electrodes CNE1 and CNE2, the light emitting elements ED, the first insulating layer PAS1, the color control structures TPL, WCL1, and WCL2, and the color filter layers CFL1, CFL2, and CFL3 sequentially disposed on the first base substrate BS may be manufactured. In the manufacturing process of the display device 10, since the process of forming the light emitting elements ED and the electrodes CNE1 and CNE2 using the separate alignment substrate AS is performed, a process of disposing the light emitting elements ED and designing and repairing the structures of the electrodes CNE1 and CNE2 may be less restricted. The finally manufactured display device 10 may have a structure including only one first base substrate BS and the display layer DL and the color control layer CL.

Hereinafter, other embodiments of the display device 10 will be described with reference to other drawings.

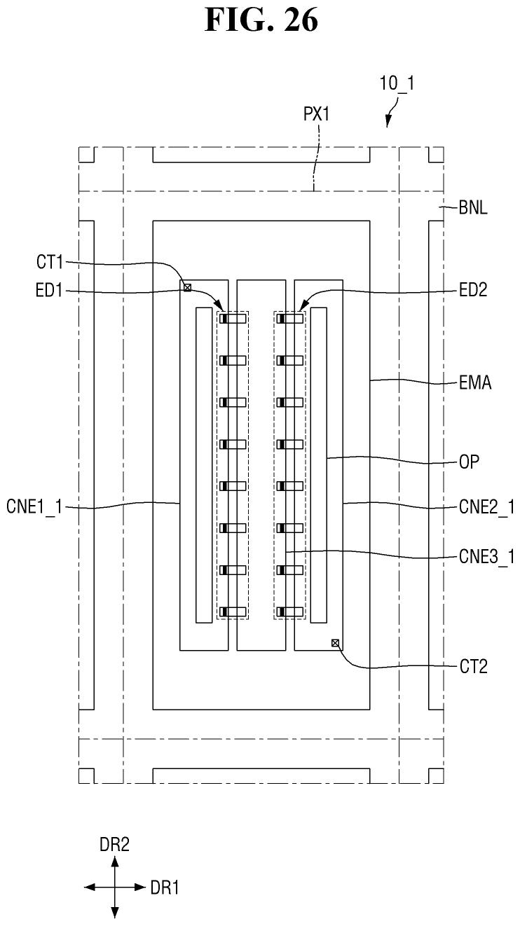

FIG. 26 is a schematic plan view illustrating an arrangement of light emitting elements and electrodes of one sub-pixel according to another embodiment.

Referring to FIG. 26, a display device 10_1 according to an embodiment may include a large number of light emitting elements ED per unit area because each of the sub-pixels PXn includes a larger number of electrodes. Each of the sub-pixels PXn may further include a third electrode CNE3_1 disposed between a first electrode CNE1_1 and a second electrode CNE2_1, and the light emitting elements ED may include first light emitting elements ED1 disposed between the first electrode CNE1_1 and the third electrode CNE3_1 and second light emitting elements ED2 disposed between the third electrode CNE3_1 and the second electrode CNE2_1. The embodiment is different from the embodiment of FIG. 3 in that structures of the electrodes CNE1_1, CNE2_1, and CNE3_1 and the light emitting elements ED disposed in each of the sub-pixels PXn are different from those of the embodiment of FIG. 3. Hereinafter, overlapping contents will be omitted and differences will be described.

Since a manufacturing process of the display device 10_1 includes a process of disposing the light emitting elements ED and forming the electrodes CNE1_1, CNE2_1, and CNE3_1 using the alignment substrate AS, there are less restrictions on arrangement structure design of the light emitting elements ED and the electrodes CNE1_1, CNE2_1, and CNE3_1. The light emitting elements ED and the electrodes CNE1_1, CNE2_1, and CNE3_1 may be disposed on a surface (or a first surface) of the first insulating layer PAS1, and the alignment substrate AS disposed on another surface (or a second surface) of the first insulating layer PAS1 may be removed. For example, the arrangement of the alignment electrodes RME1 and RME2 on the alignment substrate AS may be influenced only by the arrangement structure of the light emitting elements ED1 and ED2, regardless of the arrangement of the electrodes CNE1_1, CNE2_1, and CNE3_1.

As in the embodiment, the alignment electrodes RME1 and RME2 may be arranged in greater numbers or with different structures so that the first light emitting element ED1 and the second light emitting element ED2 are arranged in the second direction DR2, respectively. After the first light emitting elements ED1 and the second light emitting elements ED2 are disposed, the first electrode CNE1_1 in contact with an end of the first light emitting element ED1, the third electrode CNE3_1 in contact with another end of the first light emitting element ED1 and an end of the second light emitting element ED2, and the second electrode CNE2_1 in contact with another end of the second light emitting element ED2 may be formed. The third electrode CNE3_1 may have a shape extending in the second direction DR2 within the emitting material area EMA, similarly to the first and second electrodes CNE1_1 and CNE2_1. The third electrode CNE3_1 may be disposed to be spaced apart from the first and second electrodes CNE1_1 and CNE2_1 in the first direction DR1, respectively, and to cover the another end of the first light emitting element ED1 and the end of the second light emitting element ED2.

In an embodiment, the openings OP penetrating through the first insulating layer PAS1 may be formed only in areas overlapping the first electrode CNE1_1 and the second electrode CNE2_1. The third electrode CNE3_1 may not be disposed within the opening OP and may be in contact with only the light emitting elements ED1 and ED2. A first contact hole CT1 and a second contact hole CT2 may be formed only on the corresponding electrodes so that only the first electrode CNE1_1 and the second electrode CNE2_1 are electrically connected to the first transistor T1 and the second voltage line VL2 of the circuit layer. An electrical signal for light emission of the light emitting elements ED may be directly applied only to the first electrode CNE1_1 and the second electrode CNE2_1, and may be applied to the third electrode CNE3_1 through the first light emitting element ED1 or the second light emitting element ED2. Accordingly, the first light emitting element ED1 and the second light emitting element ED2 may be connected in series with each other through the third electrode CNE3_1.

It is illustrated in the drawing that ends of the first light emitting element ED1 and the second light emitting element ED2 are disposed to face the same direction, but the disclosure is not limited thereto. The first light emitting element ED1 and the second light emitting element ED2 may be disposed such that the ends face opposite directions, and the first light emitting element ED1 and the second light emitting element ED2 may be connected in series with each other by changing the arrangement and structure of the electrodes CNE1_1, CNE2_1, and CNE3_1.

Each of the sub-pixels PXn may include the light emitting elements ED1 and ED2 disposed in two columns and connected in series with each other, so that luminance per unit area may be improved. It is illustrated in the embodiment of FIG. 26 that the first light emitting element ED1 and the second light emitting element ED2 are disposed in two rows in the second direction DR2, but the disclosure is not limited thereto. For example, the first light emitting element ED1 and the second light emitting element ED2 may be arranged in the second direction DR2 in a column, and may be connected in series with each other by changing the structure of each of the electrodes.

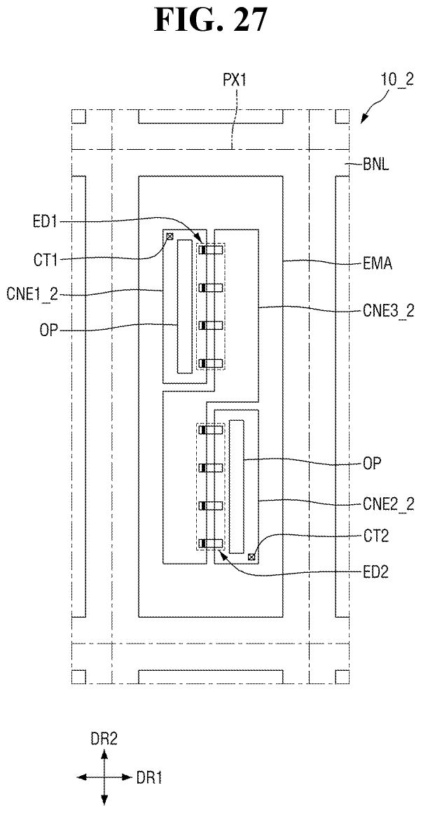

FIG. 27 is a schematic plan view illustrating an arrangement of light emitting elements and electrodes of one sub-pixel according to still another embodiment.

Referring to FIG. 27, in a display device 10_2 according to an embodiment, lengths of a first electrode CNE1_2 and a second electrode CNE2_2 extending in the second direction DR2 may be shortened, and a third electrode CNE3_2 may include a partially bent portion. The first light emitting elements ED1 and the second light emitting elements ED2 may be arranged in the second direction DR2 in a column. Each end of the first light emitting element ED1 may be in contact with the first electrode CNE1_2 and the third electrode CNE3_2, respectively, and each end of the second light emitting element ED2 may be in contact with the third electrode CNE3_2 and the second electrode CNE2_2, respectively. The third electrode CNE3_2 may include portions facing the first and second electrodes CNE1_2 and CNE2_2 and a bent portion connecting the portions, and the first light emitting element ED1 and the second light emitting element ED2 may be connected in series with each other in a column. The embodiment is different from the embodiment of FIG. 26 in that arrangements of the light emitting elements ED1 and ED2 and structures of the electrodes CNE1_2, CNE2_2, and CNE3_2 are different from those of the embodiment of FIG. 26.

In the manufacturing process of the display device 10_2, since the process of disposing the light emitting elements ED using the alignment substrate AS and forming the electrodes is performed, the structures of the electrodes CNE1_2, CNE2_2, and CNE3_2 may be not affected by the structures of the alignment electrodes RME1 and RME2 for disposing the light emitting elements ED. After the light emitting elements ED1 and ED2 are disposed using the alignment electrodes RME1 and RME2, the light emitting elements ED1 and ED2 may be connected in series with each other by designing structures of the electrodes CNE1_2, CNE2_2, and CNE3_2 in various ways.

In the embodiment of FIGS. 26 and 27, only a two-serial structure in which the first light emitting element ED1 and the second light emitting element ED2 are connected in series with each other is illustrated, but the display device 10 may also include a larger number of light emitting elements ED connected in series with each other. The display device 10 may further include electrodes that are not disposed within the opening OP and are not directly connected to the first transistor T1 and the second voltage line VL2 of the circuit layer, in addition to the first electrode CNE1 and the second electrode CNE2 disposed within in the opening OP of the first insulating layer PAS1. Different light emitting elements ED1 and ED2 connected through the electrodes may be connected in series with each other.

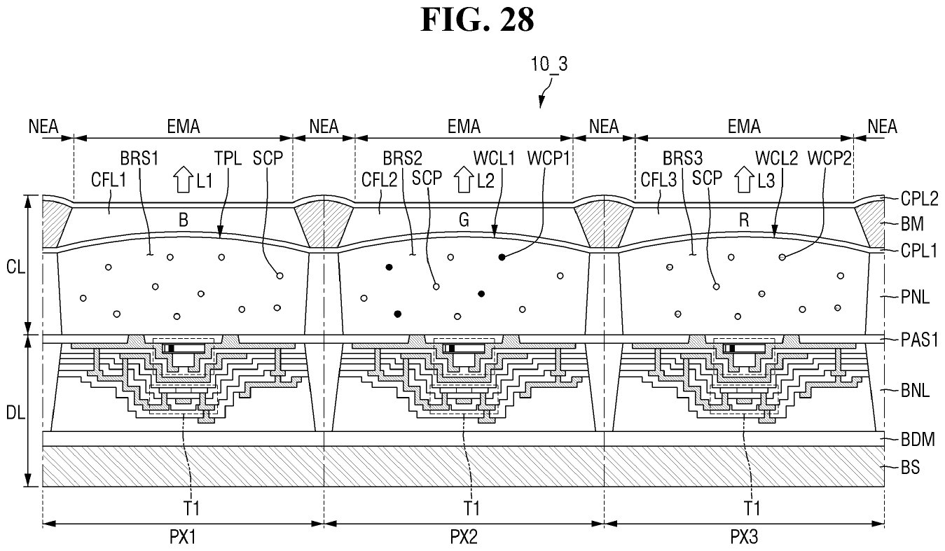

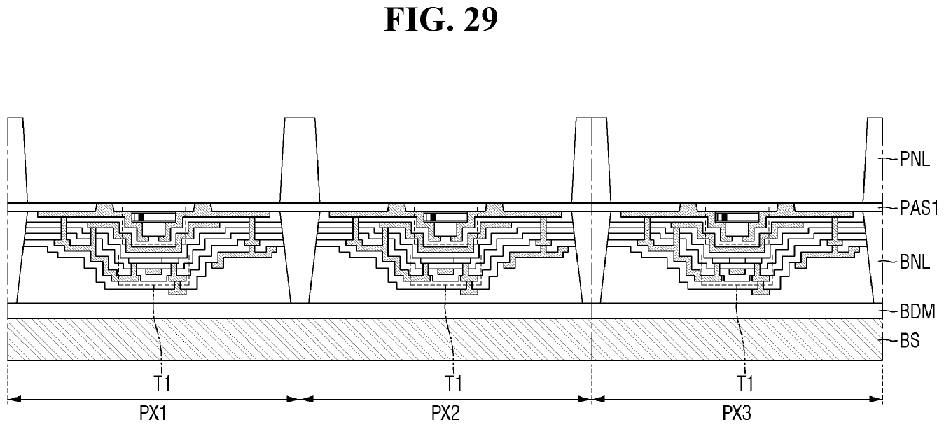

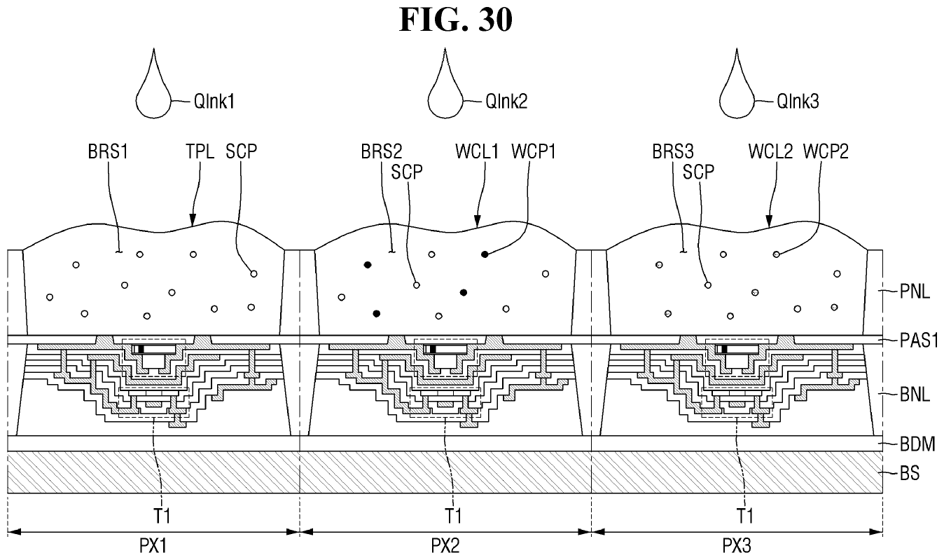

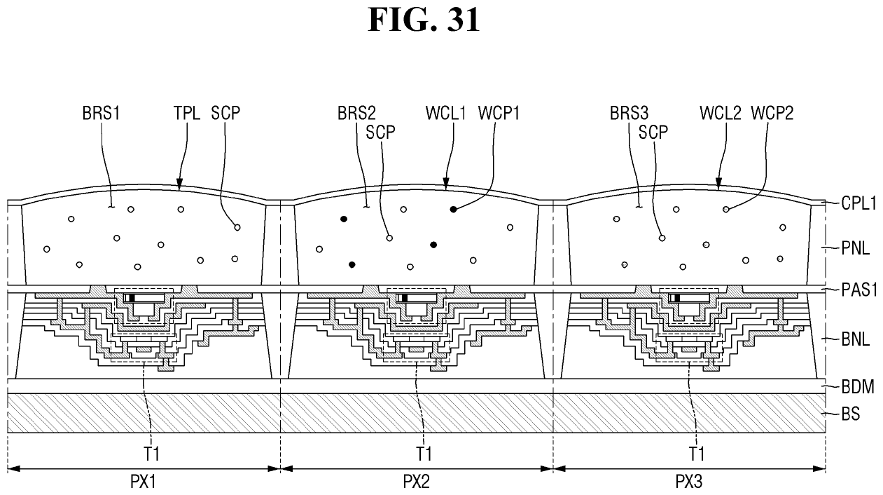

FIG. 28 is a schematic cross-sectional view illustrating one pixel of a display device according to another embodiment. FIGS. 29 to 31 are schematic cross-sectional views illustrating steps in a manufacturing process of a color control layer of the display device of FIG. 28.

Referring to FIGS. 28 to 31, a display device 10_3 may include the color control structures TPL, WCL1, and WCL2 of the color control layer CL formed through an inkjet process having a structure different from that of the embodiment of FIG. 4. The embodiment is different from the embodiment of FIG. 4 in that the color mixing preventing member MBM of the color control layer CL is omitted, a second bank PNL is disposed, and a position of the first capping layer CPL1 is changed. Hereinafter, overlapping contents will be omitted and differences will be described.

The color control layer CL may include the second bank PNL directly disposed on the second surface of the first insulating layer PAS1. The second bank PNL may be disposed in substantially the same shape as the first bank BNL. For example, the second bank PNL may be disposed in a lattice pattern on the second surface of the first insulating layer PAS1 in plan view by including portions extending in the first and second directions DR1 and DR2. The second bank PNL may be disposed across the non-emitting material area NEA or the boundary of the sub-pixels PXn on the second surface of the first insulating layer PAS1, and may form a space in which the color control structures TPL, WCL1, and WCL2 are disposed.

In an embodiment, the second bank PNL may be disposed to overlap the first bank BNL in the thickness direction, but the first bank BNL may have a shape protruding toward the first base substrate BS on the first surface of the first insulating layer PAS1, and the second bank PNL may have a shape protruding toward the color filter layers CFL1, CFL2, and CFL3 on the second surface of the first insulating layer PAS1. The first bank BNL and the second bank PNL may have a shape in which a width thereof becomes narrower in a direction protruding from the first surface or the second surface of the first insulating layer PAS1, but the disclosure is not limited thereto.

The color control structures TPL, WCL1, and WCL2 may be disposed in the space formed by the second bank PNL. The color control structures TPL, WCL1, and WCL2 may be formed by jetting ink into areas surrounded by the second banks PNL through an inkjet printing process. For example, in the manufacturing process of the display device 10_3, the second bank PNL may be formed on the second surface of the first insulating layer PAS1 of the display layer DL and the color control structures TPL, WCL1, and WCL2 may be formed between the second banks PNL.

The color control structures TPL, WCL1, and WCL2 may be formed by jetting color control inks Qink1, Qink2, and Qink3 including the scatterers SCP or the wavelength conversion materials WCP1 and WCP2 and the base resins BRS1, BRS2, and BRS3 into the area surrounded by the second bank PNL and drying the color control inks Qink1, Qink2, and Qink3. The first color control ink Qink1 including the scatterers SCP and the first base resin BRS1 may be jetted into an area corresponding to the first sub-pixel PX1, the second color control ink Qink2 including the scatterers SCP, the first wavelength conversion material WCP1, and the second base resin BRS2 may be jetted into an area corresponding to the second sub-pixel PX2, and the third color control ink Qink3 including the scatterers SCP, the second wavelength conversion material WCP2, and the third base resin BRS3 may be jetted into an area corresponding to the third sub-pixel PX3. The color control structures TPL, WCL1, and WCL2 may be formed by curing the respective color control inks Qink1, Qink2, and Qink3. The second bank PNL may prevent the color control inks Qink1, Qink2, and Qink3 from overflowing to adjacent sub-pixels PXn, and different color control structures TPL, WCL1, and WCL2 may be formed for each of the sub-pixels PXn.

The first capping layer CPL1 may be disposed on the color control structures TPL, WCL1, and WCL2. Unlike the embodiment of FIG. 4, the first capping layer CPL1 according to an embodiment may also be disposed on the second bank PNL. In case that the color control structures TPL, WCL1, and WCL2 are formed through the inkjet printing process, the color control structures TPL, WCL1, and WCL2 may be disposed after forming the second bank PNL, and as a result, the first capping layer CPL1 covering the color control structures TPL, WCL1, and WCL2 may also be disposed on the second bank PNL. According to the embodiment, as the light emitting elements ED and the color control structures TPL, WCL1, and WCL2 are formed through the inkjet printing process, respectively, the display device 10_3 may include the first bank BNL of the display layer DL and the second bank PNL of the color control layer CL.

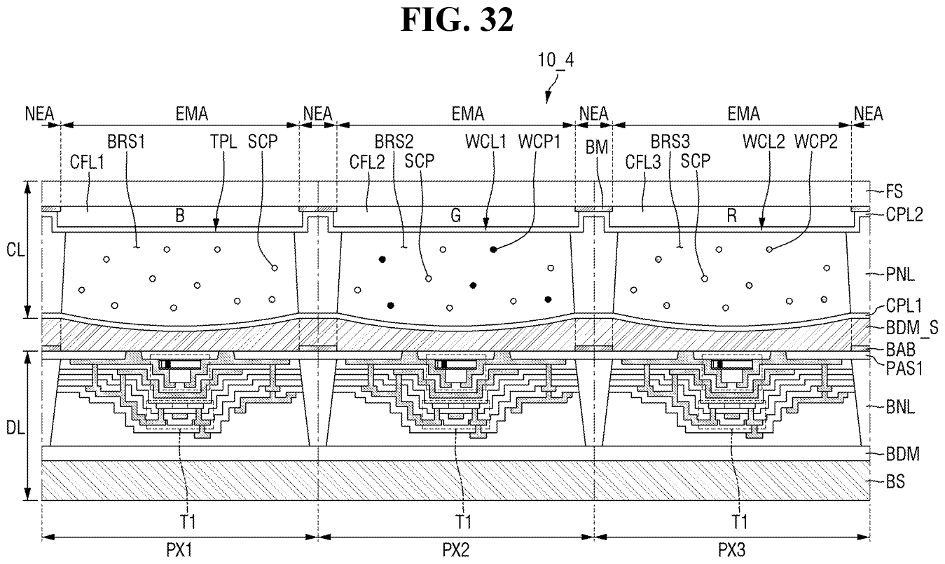

FIG. 32 is a schematic cross-sectional view illustrating one pixel of a display device according to still another embodiment.

Referring to FIG. 32, a display device 10_4 according to an embodiment may further include a second base substrate FS disposed on the color filter layers CFL1, CFL2, and CFL3 and may further include a filling layer BDM_S and a lower light absorbing member BAB disposed between the color control structures TPL, WCL1, and WCL2 and the display layer DL. The display device 10_4 may be manufactured by forming the color control structures TPL, WCL1, and WCL2 and the color filter layers CFL1, CFL2, and CFL3 on the second base substrate FS and bonding the color control structures TPL, WCL1, and WCL2 and the color filter layers CFL1, CFL2, and CFL3 to the display layer DL without directly forming the color control structures TPL, WCL1, and WCL2 on the second surface of the first insulating layer PAS1. The embodiment is different from the embodiment of FIG. 4 in that the display device 10_4 further includes the second base substrate FS and the filling layer BDM_S between the first base substrate BS and the second base substrate FS, in addition to the first base substrate BS.

The color control layer CL may be disposed on a surface of the second base substrate FS facing the first base substrate BS. The light blocking member BM and the color filter layers CFL1, CFL2, and CFL3 of the color control layer CL may be directly disposed on the surface of the second base substrate FS. The light blocking members BM may be formed to include openings exposing the surface of the second base substrate FS, and the color filter layers CFL1, CFL2, and CFL3 may be disposed on the openings of the light blocking members BM. Portions of the color filter layers CFL1, CFL2, and CFL3 may be directly disposed on the surface of the second base substrate FS, and other portions thereof may be disposed on the light blocking members BM. Different color filter layers CFL1, CFL2, and CFL3 may be disposed to be spaced apart from each other on the light blocking member BM.

The second capping layer CPL2 may be disposed on surfaces of the color filter layers CFL1, CFL2, and CFL3 and the light blocking members BM, for example, a lower surface in the drawing. The second capping layer CPL2 may be disposed to cover the color filter layers CFL1, CFL2, and CFL3 and the light blocking members BM, and may be in direct contact with the light blocking members BM at portions where the color filter layers CFL1, CFL2, and CFL3 are spaced apart from each other.

The second banks PNL may be directly disposed on the surface of the second capping layer CPL2, for example, a lower surface in the drawing, and may be disposed to overlap the light blocking members BM in the thickness direction. Unlike the embodiment of FIG. 27, the second banks PNL may have a shape protruding from the surface of the second base substrate FS toward the first base substrate BS. The second banks PNL may have a shape in which a width thereof increases from the first base substrate BS in an upward direction.

The color control structures TPL, WCL1, and WCL2 may be disposed on a surface of the second capping layer CPL2 and may be disposed in a space surrounded by the second banks PNL. The color control structures TPL, WCL1, and WCL2 and the second bank PNL may be disposed on the surface of the second capping layer CPL2. The first capping layer CPL1 may be disposed on a lower side of the color control structures TPL, WCL1, and WCL2 and the second bank PNL. A relative arrangement of the color control structures TPL, WCL1, and WCL2 and the first capping layer CPL1 is substantially the same as that of the embodiment of FIG. 27.

A lower light absorbing member BAB may be disposed on the second surface of the first insulating layer PAS1. The lower light absorbing member BAB may be disposed to overlap the first bank BNL to prevent light emitted from the light emitting elements ED from being mixed into adjacent color control structures TPL, WCL1, and WCL2. According to an embodiment, the display device 10_4 may further include the lower light absorbing member BAB to block color mixing between the sub-pixels PXn.

The lower light absorbing member BAB may include an organic material similarly to the light blocking member BM. The lower light absorbing member BAB may include a light absorbing material that absorbs light in a visible wavelength band. For example, the lower light absorbing member BAB may be made of a material used as a black matrix of the display device.

The display layer DL on the first base substrate BS and the color control layer CL on the second base substrate FS may be bonded to each other by the filling layer BDM_S. The filling layer BDM_S may serve to mutually connect the display layer DL and the color control layer CL while filling a space therebetween. The filling layer BDM_S may be disposed to be in contact with the first capping layer CPL1 and the first insulating layer PAS1. The filling layer BDM_S may be made of a Si-based organic material, an epoxy organic material, or the like, but the disclosure is not limited thereto.

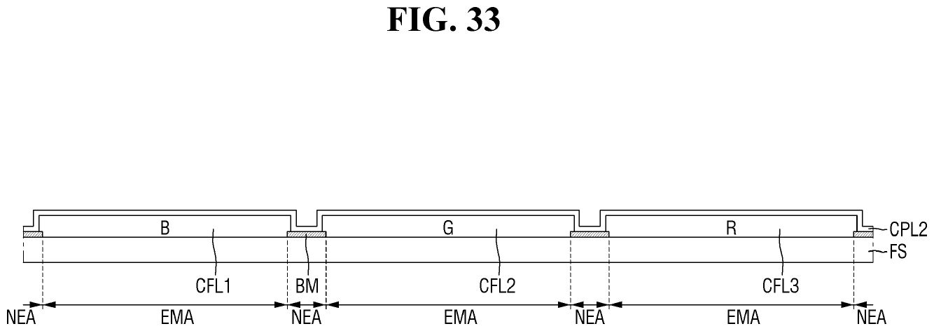

FIGS. 33 to 35 are schematic cross-sectional views illustrating steps in a manufacturing process of a color control layer of the display device of FIG. 32.

Referring to FIG. 33, the second base substrate FS may be prepared, and the light blocking member BM, the color filter layers CFL1, CFL2, and CFL3, and the second capping layer CPL2 may be formed on a surface of the second base substrate FS. The light blocking member BM may form a lattice pattern on the second base substrate FS, and the color filter layers CFL1, CFL2, and CFL3 may be disposed on the opening of the light blocking member BM.

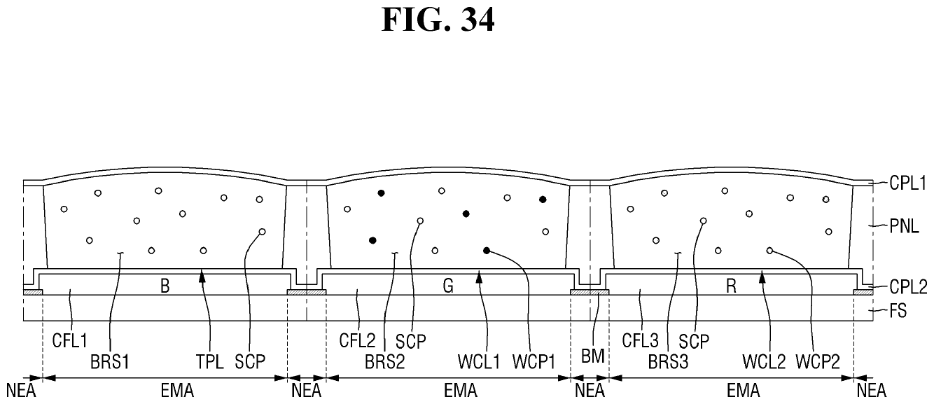

Referring to FIG. 34, the second bank PNL may be formed on the second capping layer CPL2, and the color control structures TPL, WCL1, and WCL2 disposed therebetween may be formed. The second bank PNL may be disposed on the light blocking members BM to overlap the light blocking members BM in the thickness direction, and the color control structures TPL, WCL1, and WCL2 may be disposed in an area surrounded by the second bank PNL. The color control layer CL may be formed by disposing the first capping layer CPL1 on the color control structures TPL, WCL1, and WCL2 and the second bank PNL.

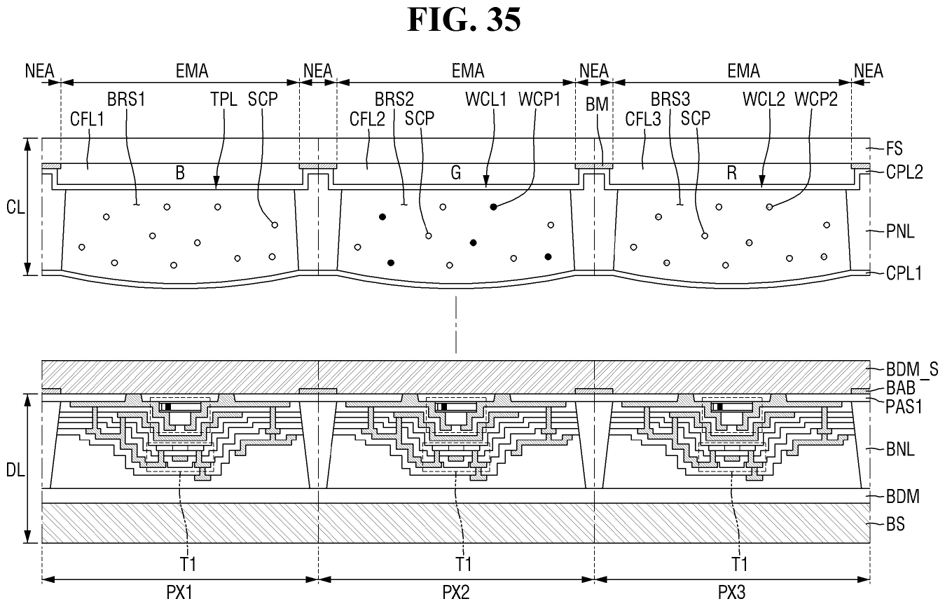

Referring to FIG. 35, the display layer DL disposed on the first base substrate BS and the color control layer CL disposed on the second base substrate FS may be bonded to each other using the filling layer BDM_S. Before bonding the display layer DL and the color control layer CL to each other, the lower light absorbing member BAB may be formed on the second surface of the first insulating layer PAS1 of the display layer DL. According to the embodiment, the display device 10_4 may have a structure including the first base substrate BS and the second base substrate FS that face each other, and the display layer DL and the color control layer CL disposed therebetween.

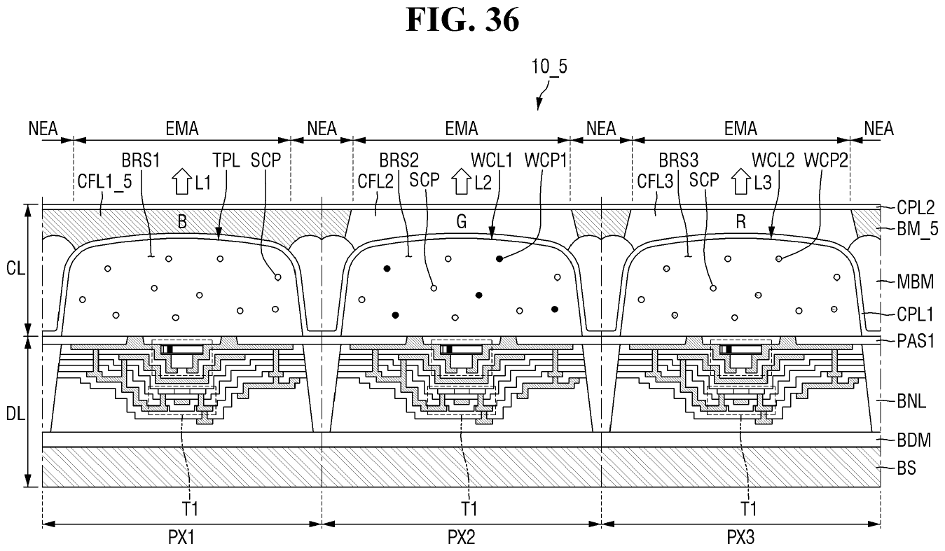

FIG. 36 is a schematic cross-sectional view illustrating one pixel of a display device according to another embodiment.

Referring to FIG. 36, in a display device 10_5 according to an embodiment, a light blocking member BM_5 may include the same colorant as a first color filter layer CFL1_5, and the light blocking members BM_5 in contact with the first color filter layer CFL1_5 may be integrated with the first color filter layer CFL1_5. The display device 10_5 of the embodiment is different from that of the embodiment of FIG. 4 in that the material of the light blocking member BM_5 is different from the material of the light blocking member BM of the embodiment of FIG. 4. Hereinafter, overlapping contents will be omitted and differences will be described.

In the display device 10_5, the light blocking members BM_5 and the first color filter layer CFL1_5 may include a same material, for example, a blue colorant. In case that the light blocking member BM_5 includes a blue colorant, external light or reflected light transmitted through the light blocking member BM_5 may have a blue wavelength band. Eye color sensibility perceived by the user's eyes may be different depending on the color of light. For example, the light of the blue wavelength band may be perceived less sensitively by the user than light of a green wavelength band and light of a red wavelength band. Therefore, as the light blocking member BM_5 includes the blue colorant, the user may perceive the reflected light relatively less sensitively.

A thickness of the light blocking member BM_5 may be substantially the same as that of the first color filter layer CFL1_5. In the process of forming the light blocking member BM_5 after the color mixing preventing member MBM is formed during the manufacturing process of the display device 10_5, the first color filter layer CFL1_5 may be formed at the same time, and the second color filter layer CFL2 and the third color filter layer CFL3 may be formed to correspond to areas where the light blocking member BM_5 and the first color filter layer CFL1_5 are not disposed. Since the light blocking member BM_5 and the first color filter layer CFL1_5 are formed at the same time, one process step may be omitted in the manufacturing process, thereby improving production efficiency.

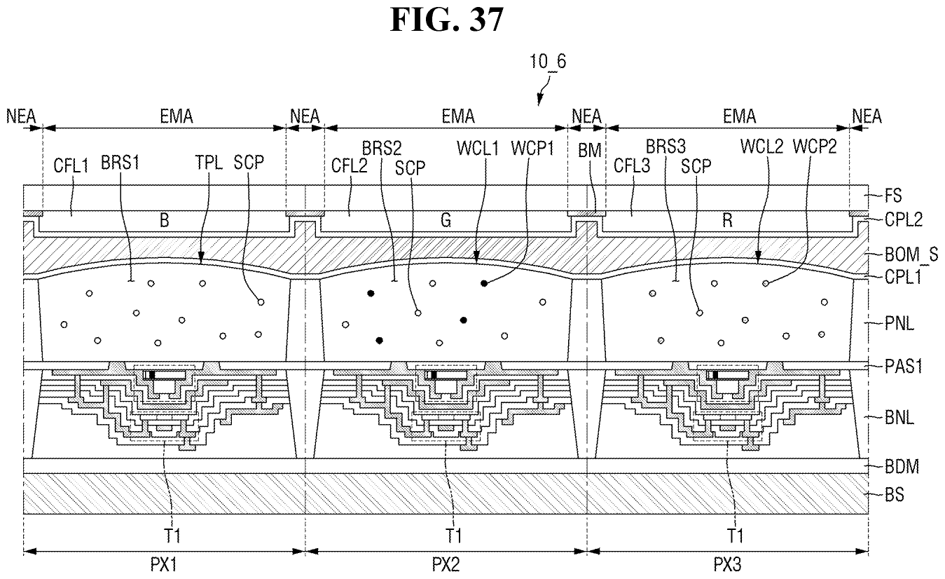

FIG. 37 is a schematic cross-sectional view illustrating one pixel of a display device according to still another embodiment.

Referring to FIG. 37, in a display device 10_6 according to an embodiment, the color filter layers CFL1, CFL2, and CFL3 may be disposed on the second base substrate FS, and the color control structures TPL, WCL1, and WCL2 may be directly disposed on the display layer DL. The second base substrate FS on which the color filter layers CFL1, CFL2, and CFL3 are disposed may be bonded to the first base substrate BS on which the color control structures TPL, WCL1, and WCL2 are disposed by the filling layer BDM_S. The embodiment is different from the embodiment of FIG. 32 in that the color control structures TPL, WCL1, and WCL2 and the color filter layers CFL1, CFL2, and CFL3 are separately formed on different base substrates (e.g., the first base substrate BS and the second base substrate FS). The display device 10_6 may be manufactured by sequentially forming the display layer DL and the color control structures TPL, WCL1, and WCL2 on the first base substrate BS and bonding the second base substrate FS on which only the color filter layers CFL1, CFL2, and CFL3 are formed to the first base substrate BS. Since the contents of other members are the same as those described above with reference to the embodiments of FIGS. 4 and 32, detailed descriptions thereof will be omitted. It is illustrated in the above-described embodiments that based on the light emitting element ED emitting blue, which is a first color, the light transmission layer TPL or the wavelength conversion layers WCL1 and WCL2 may be disposed as the color control structures according to the sub-pixel PXn. However, the disclosure is not limited thereto, and in some embodiments, the color of light incident on the color filter layers CFL1, CFL2, and CFL3 may be controlled by changing the color control structures or the light emitting elements.

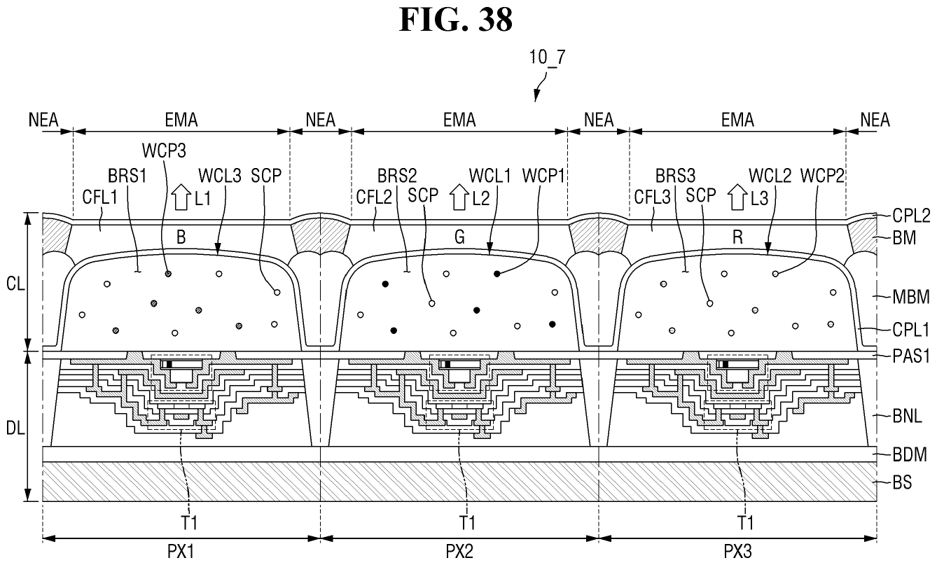

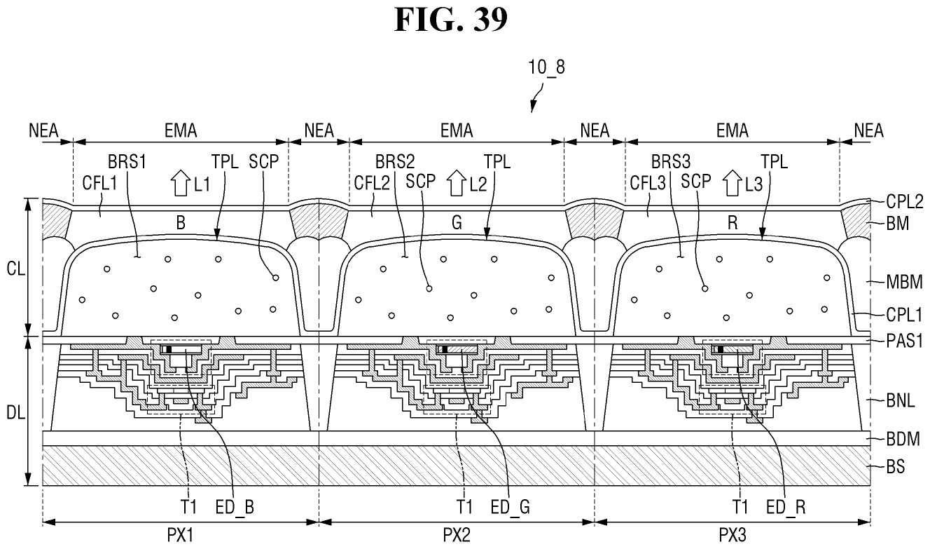

FIGS. 38 and 39 are schematic cross-sectional views illustrating one pixel of a display device according to still another embodiment.

First, referring to FIG. 38, a display device 10_7 according to an embodiment may include a third wavelength conversion layer WCL3 as a color control structure disposed in the first sub-pixel PX1. In the embodiment in which the light emitting element ED emits blue light of the first color L1, the display device 10_7 may include the third wavelength conversion layer WCL3 including a third wavelength conversion material WCP3 disposed in the first sub-pixel PX1 to adjust a central wavelength band of the light emitted from the light emitting element ED. The embodiment is different from the embodiment of FIG. 4 in that the third wavelength conversion layer WCL3 is disposed instead of the light transmission layer TPL.

Similarly to the first wavelength conversion layer WCL1, the third wavelength conversion layer WCL3 may include the first base resin BRS1, the third wavelength conversion material WCP3, and the scatterer SCP. The third wavelength conversion material WCP3 may adjust the light L1 of the first color emitted from the light emitting element ED. The light emitted from the light emitting element ED and the light adjusted by the third wavelength conversion material WCP3 and emitted may be light close to blue. In case that the central wavelength band of light to be emitted from the first sub-pixel PX1 of the display device 10_7 is different from the central wavelength band of light emitted from the light emitting element ED, the color control structure of the first sub-pixel PX1 may be the third wavelength conversion layer WCL3 instead of the light transmission layer TPL. For example, the display device 10_7 may control the color of light displayed in each of the sub-pixels PXn through the wavelength conversion layers WCL1, WCL2, and WCL3 of the color control structure and the color filter layers CFL1, CFL2, and CFL3 regardless of the central wavelength band or color of the light emitted from the light emitting element ED.

Referring to FIG. 39, a display device 10_8 according to an embodiment may include light emitting elements ED_B, ED_G, and ED_R emitting light of different colors for each of the sub-pixels PXn, and may include the light transmission layers TPL each disposed as the color control structure. The display device 10_8 of FIG. 39 is different from that of the embodiment of FIG. 38 in that the color control structures disposed in each of the sub-pixels PXn are the same, but the types of the light emitting elements ED are different.

For example, the light emitting element ED_B disposed in the first sub-pixel PX1 may emit blue light of a first color, the light emitting element ED_G disposed in the second sub-pixel PX2 may emit green light of a second color, and the light emitting element ED_R disposed in the third sub-pixel PX3 may emit red light of a third color. Accordingly, even in case that all of the color control structures of each of the sub-pixels PXn are light transmission layers TPL, light incident on the color filter layers CFL1, CFL2, and CFL3 may have different colors. Even in case that the color control structures include only the light transmission layer TPL, the display device 10_8 may control the color of light displayed by each of the sub-pixels PXn by the types of the light emitting elements ED_B, ED_G, and ED_R and the color filter layers CFL1, CFL2, and CFL3.

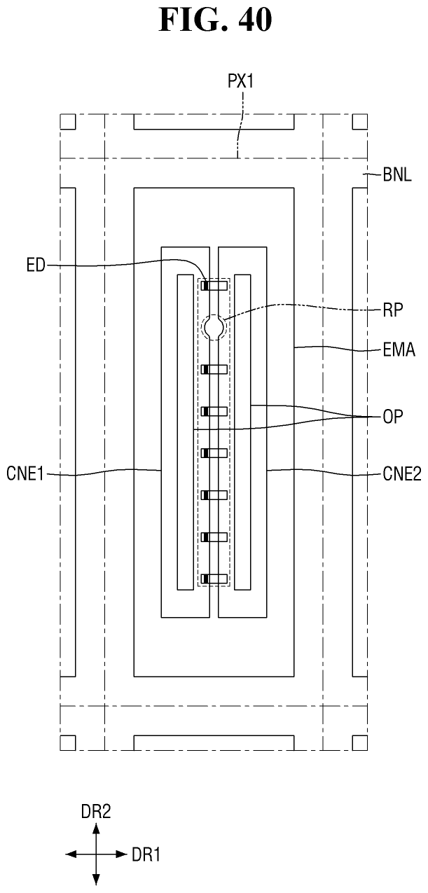

FIG. 40 is a schematic plan view illustrating an arrangement of light emitting elements and electrodes of one sub-pixel of a display device according to another embodiment.

Referring to FIG. 40, the display device 10 according to an embodiment may include a first pattern RP formed in each of the sub-pixels PXn. The first pattern RP may be formed in a shape in which a gap between the first electrode CNE1 and the second electrode CNE2 is different from other portions. The first pattern RP may be a portion having a curved shape in which a portion of sides of each of the first and second electrodes CNE1 and CNE2 facing each other are depressed.

In the process of disposing the light emitting elements ED on the alignment substrate AS, in case that the light emitting elements ED are not disposed at desired positions or the electrodes CNE1 and CNE2 are directly connected to each other and shorted, a repair process for supplementing such a problem may be performed. Light emitting elements ED that are not disposed at specific positions may act as foreign substances in a subsequent process, and in case that the electrodes CNE1 and CNE2 are shorted to each other, the corresponding sub-pixel PXn may not emit light. In the manufacturing method for the display device 10, a repair process may be performed before forming the circuit layer, and the display device 10 may include traces of the repair process.

For example, in case that the electrodes CNE1 and CNE2 are directly connected and shorted, a repair process for removing a portion where the first electrode CNE1 and the second electrode CNE2 are connected may be performed. In an embodiment, the repair process may be performed as a process of removing a material constituting the light emitting element ED or the electrodes CNE1 and CNE2 by irradiating a laser, and some sub-pixels PXn of the display device 10 may include the first pattern RP formed by removing the shorted electrodes CNE1 and CNE2. The first pattern RP, which is a portion where the first electrode CNE1 and the second electrode CNE2 are connected and removed, may be a portion having a curved shape in which a portion of sides of each of the first electrode CNE1 and the second electrode CNE2 facing each other are partially depressed. Substantially, the first pattern RP may not be a trace where a specific member is disposed, but may be a trace remaining in case that the first electrode CNE1 and the second electrode CNE2 are partially removed. However, the shape and structure of the first pattern RP is not limited to that illustrated in the drawing, and the display device 10 may also include first patterns RP having various structures and positions as traces of the repair process.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

1. A display device comprising:
a first base substrate on which a plurality of sub-pixels are defined;
a first insulating layer disposed on the first base substrate and including a first surface and a second surface, the first surface facing the first base substrate;
a plurality of light emitting elements disposed in, each of the plurality of sub-pixels on the first surface of the first insulating layer;
a first electrode and a second electrode directly disposed on the first surface of the first insulating layer and electrically contacting each end of each of the plurality of light emitting elements, respectively;
a circuit layer disposed between the first and second electrodes and the first base substrate and including a first transistor electrically connected to each of the plurality of light emitting elements;
a color control structure disposed on the second surface of the first insulating layer and including a light transmission layer and wavelength conversion layers; and
a color filter layer disposed on the color control structure.

2. The display device of claim 1, further comprising:
a first bank disposed on the first surface of the first insulating layer and having a shape protruding toward the first base substrate, wherein
the first bank is disposed at a boundary of the plurality of sub-pixels, and
the plurality of light emitting elements, the first electrode, and the second electrode are disposed in an area surrounded by the first bank.

3. The display device of claim 2, wherein
the circuit layer further includes a lower metal layer disposed between the first transistor and the plurality of light emitting elements, and
the lower metal layer is disposed to overlap the plurality of light emitting elements in a thickness direction of the first base substrate.

4. The display device of claim 2, wherein
the first insulating layer includes a plurality of openings penetrating from the first surface to the second surface, and
each of the first electrode and the second electrode has a portion disposed in one of the plurality of openings.

5. The display device of claim 4, wherein
the first electrode and the second electrode extend in a direction and are disposed to be spaced apart from each other, and
the plurality of light emitting elements are arranged to be spaced apart in the direction in which the first electrode and the second electrode extend.

6. The display device of claim 5, wherein
the plurality of light emitting elements include a first light emitting element and a second light emitting element spaced apart from the first light emitting element,
the first electrode electrically contacts an end of the first light emitting element,
the second electrode electrically contacts an end of the second light emitting element, and
the display device further includes a third electrode electrically contacting another end of the first light emitting element and another end of the second light emitting element.

7. The display device of claim 2, further comprising:
a first pattern having a curved shape in which a portion of sides of each of the first electrode and the second electrode facing each other are depressed.

8. The display device of claim 2, further comprising:
a bonding agent disposed between the circuit layer and the first base substrate.

9. The display device of claim 2, wherein
the plurality of sub-pixels include a first sub-pixel and a second sub-pixel,
the color control structure includes the light transmission layer disposed in the first sub-pixel and a first wavelength conversion layer disposed in the second sub-pixel, and
the color filter layer includes a first color filter layer disposed in the first sub-pixel and a second color filter layer disposed in the second sub-pixel.

10. The display device of claim 9, further comprising:
a first capping layer disposed on the light transmission layer and the first wavelength conversion layer; and
a light blocking member disposed on the first capping layer and surrounding the first color filter layer and the second color filter layer.

11. The display device of claim 10, wherein
the first capping layer is disposed to surround the light transmission layer and the first wavelength conversion layer, and
the display device further includes a color mixing preventing member disposed on the first capping layer between the light transmission layer and the first wavelength conversion layer.

12. The display device of claim 10, further comprising:
a second bank disposed between the light transmission layer and the first wavelength conversion layer,
wherein the first capping layer is disposed on the second bank.

13. The display device of claim 10, further comprising:
a second base substrate disposed on the color filter layer and the light blocking member and directly contacting the light blocking member; and
a filling layer disposed between the first insulating layer and the color control structure.

14. The display device of claim 9, wherein
light emitted from the plurality of light emitting elements disposed in the first sub-pixel passes through the light transmission layer and is emitted through the first color filter layer, and
light emitted from the plurality of light emitting elements disposed in the second sub-pixel passes through the first wavelength conversion layer and is emitted through the second color filter layer.

15. The display device of claim 14, wherein
the plurality of light emitting elements disposed in the first sub-pixel and the second sub-pixel emit light of a first color,
the first sub-pixel emits light of the first color, and
the second sub-pixel emits light of a second color different from the first color.

16. The display device of claim 15, wherein
the plurality of sub-pixels further include a third sub-pixel,
the color control structure further includes a second wavelength conversion layer disposed in the third sub-pixel,
the color filter layer further includes a third color filter layer disposed in the third sub-pixel, and
light emitted from the plurality of light emitting elements disposed in the third sub-pixel passes through the second wavelength conversion layer and is emitted as light of a third color different from the first color and the second color through the third color filter layer.

17. A manufacturing method for a display device, the manufacturing method comprising:
preparing an alignment substrate including a target substrate and alignment electrodes disposed to be spaced apart from each other on the target substrate;
forming a display element substrate by disposing light emitting elements on a first surface of a first insulating layer disposed on the alignment substrate, forming a plurality of electrodes and a circuit layer on the light emitting elements, and bonding the display element substrate on which the circuit layer is formed to a first base substrate;
removing the alignment substrate from the display element substrate to expose a second surface of the first insulating layer; and
disposing a color control structure and a color filter layer on the second surface of the first insulating layer.

18. The manufacturing method of claim 17, wherein
the alignment substrate further includes an auxiliary layer disposed on the target substrate, and
the alignment electrodes include a first alignment electrode and a second alignment electrode extending in a direction and disposed to be spaced apart from each other.

19. The manufacturing method of claim 18, wherein
the plurality of electrodes include a first electrode and a second electrode disposed directly on the first surface of the first insulating layer and electrically contacting each end of each of the light emitting elements, respectively, and
the forming of the display element substrate includes forming the first electrode and the second electrode after the disposing of the light emitting elements on the first surface of the first insulating layer by generating an electric field on the alignment electrodes.

20. The manufacturing method of claim 19, wherein the circuit layer is disposed on the light emitting elements and the plurality of electrodes.

21. The manufacturing method of claim 19, wherein the forming of the display element substrate further includes forming a first pattern by removing a portion where the first electrode and the second electrode are connected to each other.

22. The manufacturing method of claim 18, wherein the removing of the alignment substrate from the display element substrate includes:
separating the target substrate from the auxiliary layer; and
etching and removing the auxiliary layer and the alignment electrodes.

23. The manufacturing method of claim 18, wherein the disposing of the color control structure and the color filter layer includes directly disposing the color control structure on the second surface of the first insulating layer.

24. The manufacturing method of claim 18, wherein the disposing of the color control structure and the color filter layer includes:
preparing a second base substrate;
forming the color filter layer and the color control structure on the second base substrate; and
bonding the color control structure and the second surface of the first insulating layer to each other using a filler.
